(19) United States
(12) Patent Application Publication
(10) Pub. No.: US 2024/0355823 A1
(43) Pub. Date: Oct. 24, 2024

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Chia-Ling PAI, Taichung City (TW); Chih-Yang HUANG, Pintung County (TW)

(73) Assignee: TAIWAN SEMICONDUCTOR MANUFACTURING COMPANY, LTD., Hsinchu (TW)

(21) Appl. No.: 18/306,101

(22) Filed: Apr. 24, 2023

(51) Int. Cl. H01L 27/092; H01L 21/8238; H01L 29/04; H01L 29/06; H01L 29/423; H01L 29/775

(52) U.S. Cl. CPC H01L 27/0922; H01L 21/823878; H01L 29/045; H01L 29/0673; H01L 29/42392; H01L 29/775

(57) ABSTRACT

A semiconductor device includes a first transistor and a second transistor over the first transistor, the second transistor having a different conductivity type than the first transistor. The first transistor includes a first semiconductor channel layer, in which the first semiconductor channel layer has a first crystalline orientation, a first gate structure wrapping around the first semiconductor channel layer, and first source/drain epitaxy structures on opposite ends of the first semiconductor channel layer. The second transistor includes a second semiconductor channel layer, wherein the second semiconductor channel layer has a second crystalline orientation different from the first crystalline orientation, a second gate structure wrapping around the second semiconductor channel layer, and second source/drain epitaxy structures on opposite ends of the second semiconductor channel layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2A to 17B illustrate a method in various stages of forming a semiconductor device in accordance with some embodiments of the present disclosure.

FIGS. 18A and 18B illustrate a semiconductor device in accordance with some embodiments of the present disclosure.

FIGS. 19A to 35B illustrate a method in various stages of forming a semiconductor device in accordance with some embodiments of the present disclosure.

FIGS. 36 to 38B illustrate a method in various stages of forming a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

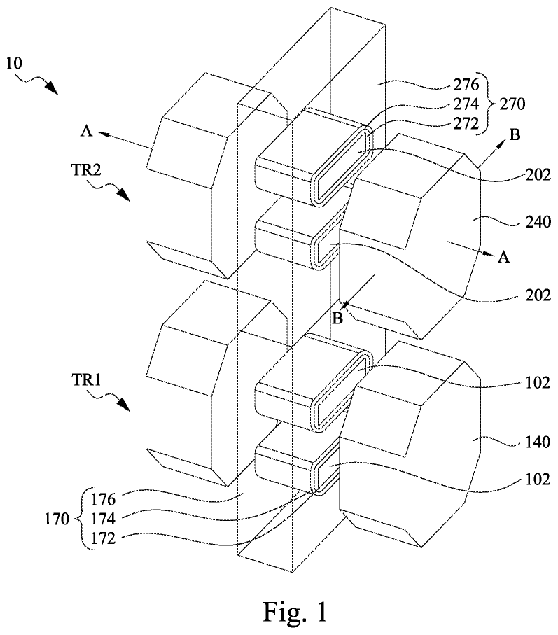

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, a first transistor TR1 is disposed over a substrate (not shown), and a second transistor TR2 is disposed vertically above the first transistor TR1. In some embodiments, the first transistor TR1 and the second transistor TR2 may be field effect transistor (FET) and may both include gate-all-around (GAA) configuration, and thus the first transistor TR1 and the second transistor TR2 can also be referred to as GAA FET. The first transistor TR1 includes first semiconductor channel layers 102 vertically stacked one above another, a first metal gate structure 170 wrapping around each of the first semiconductor channel layers 102, and first source/drain epitaxy structures 140 on opposite ends of each of the first semiconductor channel layers 102. Similarly, the second transistor TR2 includes second semiconductor channel layers 202 vertically stacked one above another, a second metal gate structure 270 wrapping around each of the second semiconductor channel layers 202, and second source/drain epitaxy structures 240 on opposite ends of each of the second semiconductor channel layers 202. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276.

In some embodiments, the first transistor TR1 has a first conductivity type and the second transistor TR2 has a second conductivity type different from the first conductivity type. For example, the first transistor TR1 may be an n-type transistor (e.g., N-FET), and the second transistor TR2 may be a p-type transistor (e.g., P-FET). However, in other embodiments, the first transistor TR1 may be a p-type transistor (e.g., P-FET), and the second transistor TR2 may be an n-type transistor (e.g., N-FET). For an n-type transistor, the source/drain epitaxy structures (e.g., the first source/drain epitaxy structures 140 and/or the second source/drain epitaxy structures 240) may include n-type dopants, such as phosphorus (P), arsenic (As), or antimony (Sb), or the like. For a p-type transistor, the source/drain epitaxy structures (e.g., the first source/drain epitaxy structures 140 and/or the second source/drain epitaxy structures 240) may include p-type dopants, such as boron (B), gallium (Ga), indium (In), aluminium (Al), or the like.

In some embodiments of the present disclosure, the first semiconductor channel layers 102 and the second semiconductor channel layers 202 may include different crystalline orientations. Experiment results show that a silicon channel with (100) crystalline orientation has an electron mobility of 350 cm²/V-S, which is higher than the electron mobility of silicon channel with (110) crystalline orientation (e.g., 230 cm²/V-S) and the electron mobility of silicon channel with (111) crystalline orientation (e.g., 300 cm²/V-S). On the other hand, a silicon channel with (110) crystalline orientation has a hole mobility of 180 cm²/V-S, which is higher than the hole mobility of silicon channel with (100) crystalline orientation (e.g., 75 cm²/V-S) and the hole mobility of silicon channel with (111) crystalline orientation (e.g., 120 cm²/V-S). Accordingly, it can be seen that silicon channel with (100) crystalline orientation may be suitable for n-type device, while silicon channel with (110) crystalline orientation may be suitable for p-type device.

As a result, in the embodiments where the first transistor TR1 is an n-type transistor (e.g., N-FET) and the second transistor TR2 is a p-type transistor (e.g., P-FET), the first semiconductor channel layers 102 and the second semiconductor channel layers 202 may include (100) crystalline orientation and (110) crystalline orientation, respectively. On the other hand, in the embodiments where the first transistor TR1 is a p-type transistor (e.g., P-FET) and the second transistor TR2 is an n-type transistor (e.g., N-FET), the first semiconductor channel layers 102 and the second semiconductor channel layers 202 may include (110) crystalline orientation and (100) crystalline orientation, respectively. By selecting a proper crystalline orientation for the channel layer, the device performance may be improved.

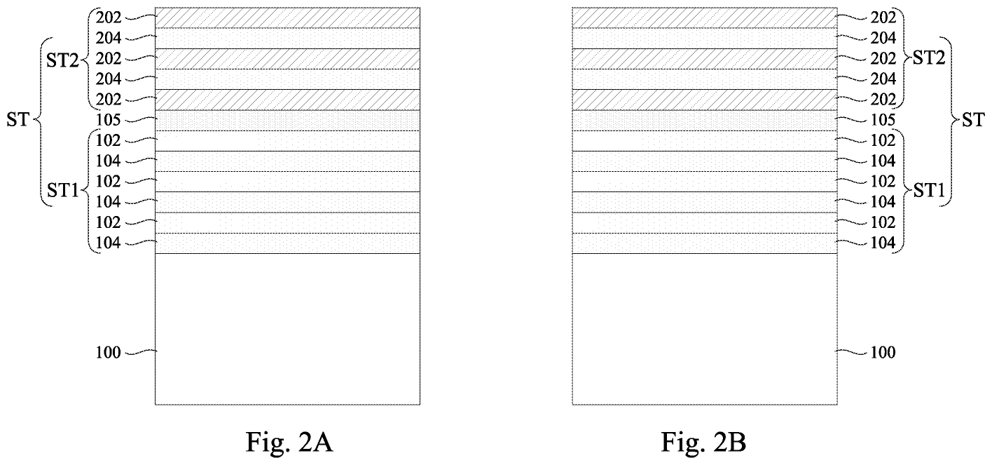

FIGS. 2A to 17B illustrate a method in various stages of forming a semiconductor device in accordance with some embodiments of the present disclosure. It is noted that FIGS. 2A, 3A, 4A, 5A, 6A, 7A, 8A, 9A, 10A, 11A, 12A, 13A, 14A, 15A, 16A, and 17A include cross-sectional views the same as the cross-sectional view along line A-A of FIG. 1, and FIGS. 2B, 3B, 4B, 5B, 6B, 7B, 8B, 9B, 10B, 11B, 12B, 13B, 14B, 15B, 16B, and 17B include cross-sectional views the same as the cross-sectional view along line B-B of FIG. 1. Although FIGS. 2A to 17B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 17B may be similar to those described with respect to FIG. 1, and thus relevant details will not be repeated for brevity.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A stack ST is formed over the substrate 100. The stack ST includes a first stack ST1 of alternating semiconductor layers 102 and 104, a crystalline orientation switching layer 105 disposed over the first stack ST1, and a second stack ST2 of alternating semiconductor layers 202 and 204 over the crystalline orientation switching layer 105. In some embodiments, the semiconductor layers 102 and 202 may be made of pure silicon layers that are free of germanium. In some embodiments, the semiconductor layers 102 and 202 may also be substantially pure silicon layers, for example, with a germanium percentage lower than about 1 percent. The semiconductor layers 104 and 204 may be made of silicon germanium. For example, the germanium percentage (atomic percentage concentration) of the semiconductor layers 104 and 204 may be in a range from about 20 percent and about 40 percent. In some embodiments, the semiconductor layers 102, 104, 202, and 204 may be deposited using suitable deposition process, such as selective epitaxial growth (SEG), chemical vapor deposition (CVD), molecular beam epitaxy (MBE), or other suitable process(es). In some embodiments, the semiconductor layers 104 and 204 may be removed during a replacement gate (RPG) process, and thus the semiconductor layers 104 and 204 can also be referred to as sacrificial layers. In some embodiments, the crystalline orientation switching layer 105 may be deposited using suitable deposition process, such as molecular beam epitaxy (MBE), atomic layer chemical vapor deposition (ALCVD).

In some embodiments, the substrate 100 may include a first crystalline orientation. For example, the first crystalline orientation may be (100) crystalline orientation or (110) crystalline orientation. The semiconductor layers 102 and 104 are alternately deposited over the substrate 100. Due to the nature of epitaxial growth, the semiconductor layers 102 and 104 tend to have a same crystalline orientation as the substrate 100. Thus, the semiconductor layers 102 and 104 may also include a first crystalline orientation.

The crystalline orientation switching layer 105 is then deposited over the first stack ST1. For example, the crystalline orientation switching layer 105 is deposited over the topmost semiconductor layer 102 of the first stack ST1. The crystalline orientation switching layer 105 may include a second crystalline orientation that is different from the first crystalline orientation of the substrate 100 and the semiconductor layers 102 and 104. For example, if the first crystalline orientation is (100) crystalline orientation, the second crystalline orientation is (110) crystalline orientation. Similarly, if the first crystalline orientation is (110) crystalline orientation, the second crystalline orientation is (100) crystalline orientation.

The crystalline orientation switching layer 105 may be made of a dielectric material, such as a metal oxide. In some embodiments, the metal oxide may include yttrium oxide (Y₂O₃), cerium oxide (CeO₂), complex oxide system (such as (LaₓY₁₋ₓ)₂O₃ (LaYO), or containing more than two kinds of metal elements), or the like. In some embodiments, because oxygen and silicon include similar lattice constants, the silicon atoms may be bonded with oxygen atoms in the dielectric layer due to less lattice mismatch, and thus the crystalline orientation switching layer 105 can be epitaxially grown over a semiconductor layer (e.g., the topmost semiconductor layer 102) without strong lattice mismatch issue.

Furthermore, experiment results also show that the crystalline orientation of the crystalline orientation switching layer 105 is controllable during depositing the crystalline orientation switching layer 105 over a semiconductor layer (e.g., the topmost semiconductor layer 102). More specifically, the crystalline orientation of the crystalline orientation switching layer 105 is temperature dependent during the deposition process. That is, by controlling the deposition temperature of the crystalline orientation switching layer 105, a crystalline orientation switching layer 105 having a desired crystalline orientation can be obtained.

For example, in some embodiments where the topmost semiconductor layer 102 is made of silicon and has a (100) crystalline orientation, the deposition temperature with about 400° C. to 500° C. (e.g., 450° C. in this case) may result in a crystalline orientation switching layer 105 having (110) crystalline orientation. If the deposition temperature is beyond the range, the crystalline orientation switching layer 105 may include unwanted crystalline orientation. For example, if the deposition temperature is about 60° C., the crystalline orientation switching layer 105 may include random-crystalline orientation (e.g., polycrystalline). If the deposition temperature is about 270° C., the crystalline orientation switching layer 105 may include (111) crystalline orientation.

In some embodiments where the substrate 100 and the semiconductor layers 102 and 104 include (100) crystalline orientation, the deposition temperature of the semiconductor layers 102 and 104 may be about 600° C. to about 700° C. That is, the deposition temperature of the semiconductor layers 102 and 104 may be higher than the deposition temperature of the crystalline orientation switching layer 105.

Based on the above discussion, it can be seen that by selecting the material and the deposition temperature of the crystalline orientation switching layer 105, the crystalline orientation of the crystalline orientation switching layer 105 can be switched from the first crystalline orientation of the substrate 100 and the semiconductor layers 102 and 104 to a second crystalline orientation. The switched crystalline orientation is beneficial for allowing the following growth semiconductor layers 202 and 204 having a different crystalline orientation than the substrate 100 and the semiconductor layers 102 and 104.

The semiconductor layers 202 and 204 are alternately deposited over the crystalline orientation switching layer 105. Due to the nature of epitaxial growth, the semiconductor layers 202 and 204 tend to have a same crystalline orientation as the crystalline orientation switching layer 105. Thus, the semiconductor layers 202 and 204 may also include a second crystalline orientation the same as the crystalline orientation switching layer 105. That is, although the semiconductor layers 102 and 202 may be made of a same material (e.g., silicon), the semiconductor layers 102 and 202 may include different crystalline orientations. Similarly, although the semiconductor layers 104 and 204 may be made of a same material (e.g., silicon germanium), the semiconductor layers 104 and 204 may include different crystalline orientations.

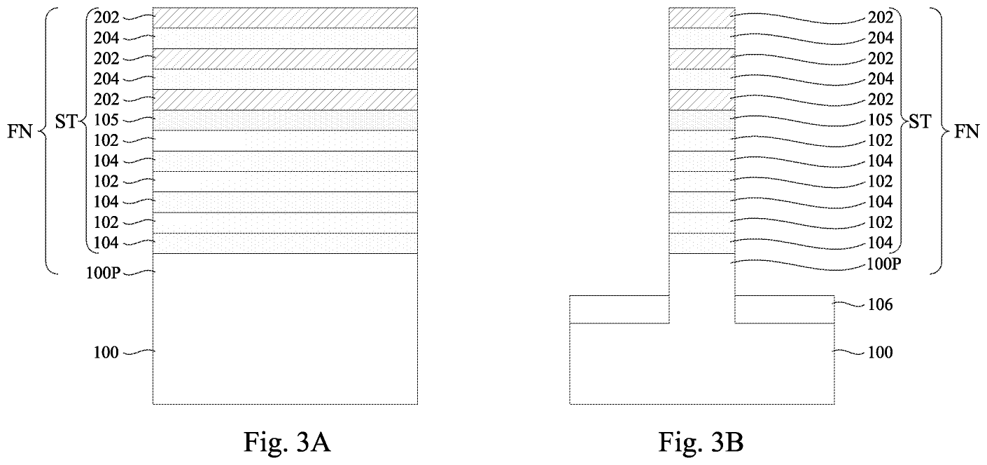

Reference is made to FIGS. 3A and 3B. A patterning process is performed to the stack ST and the substrate 100 to form a fin structure FN. In some embodiments, the patterning process may include forming a patterned photoresist layer over the stack ST, and then performing an etching process to remove unwanted portions of the stack ST and the substrate 100 exposed by the patterned photoresist layer. The fin structure FN may include a remaining portion of the stack ST and a semiconductor strip 100P protruding over the substrate 100. In some embodiments, the etching process may include wet etch, dry etch, or the like.

After the fin structure FN is formed, isolation structures 106 are formed over the substrate 100 and laterally surrounding the fin structure FN. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

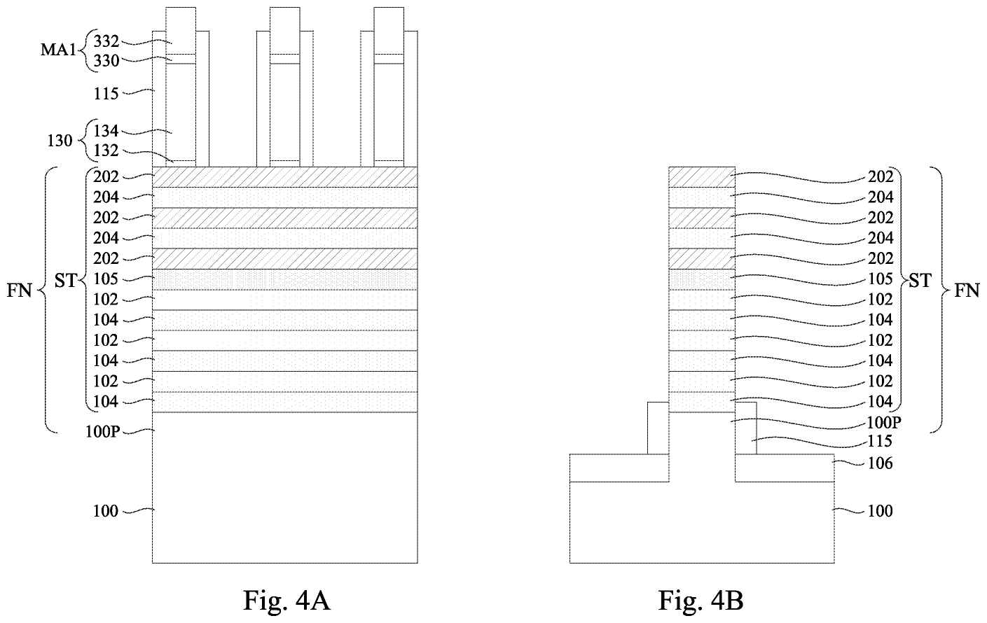

Reference is made to FIGS. 4A and 4B. Dummy gate structures 130 are formed over the substrate 100 and crossing the fin structure FN. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, each of the patterned masks MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

Spacers 115 are formed on opposite sidewalls of each of the dummy gate structures 130 (see FIG. 4A), and on opposite sidewalls of the fin structure FN (see FIG. 4B). In some embodiments, portions of the spacers 115 on opposite sidewalls of each of the dummy gate structures 130 can be referred to as gate spacers, and portions of the spacers 115 on opposite sidewalls of the fin structure FN can be referred to as fin spacers. In some embodiments, the fin spacers are landed on the isolation structures 106, and may be kept or removed in later processes, depending on embodiments. In some embodiments, the spacers 115 may be formed of silicon oxide, silicon nitride, silicon oxynitride, combinations thereof. In some embodiments, the spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130 and on sidewalls of the fin structure FN. In some embodiments, the remaining vertical portions of the spacer layer can be referred to as the spacers 115. The spacer layer may be deposited using techniques such CVD, ALD, or the like.

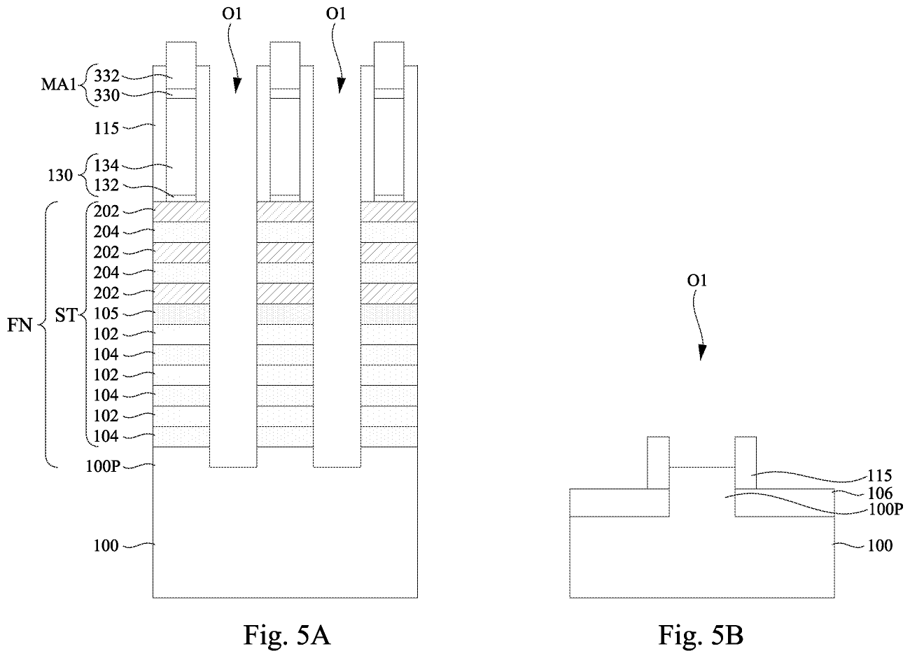

Reference is made to FIGS. 5A and 5B. An etching process is performed to remove portions of the fin structure FN (or stack ST) by using the dummy gate structures 130 and the spacers 115 as etch mask, so as to form source/drain openings O1 in the fin structure FN (or in the stack ST). In some embodiments, the etching process may be wet etch, dry etch, or combinations thereof. In some embodiments, the bottommost ends of the source/drain openings O1 may be lower than the bottommost semiconductor layer 104.

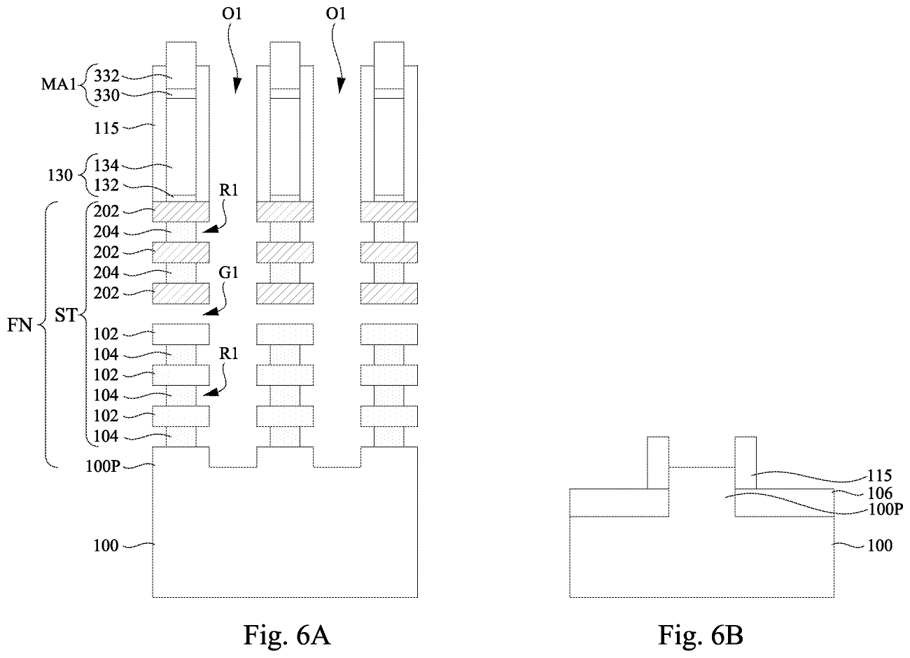

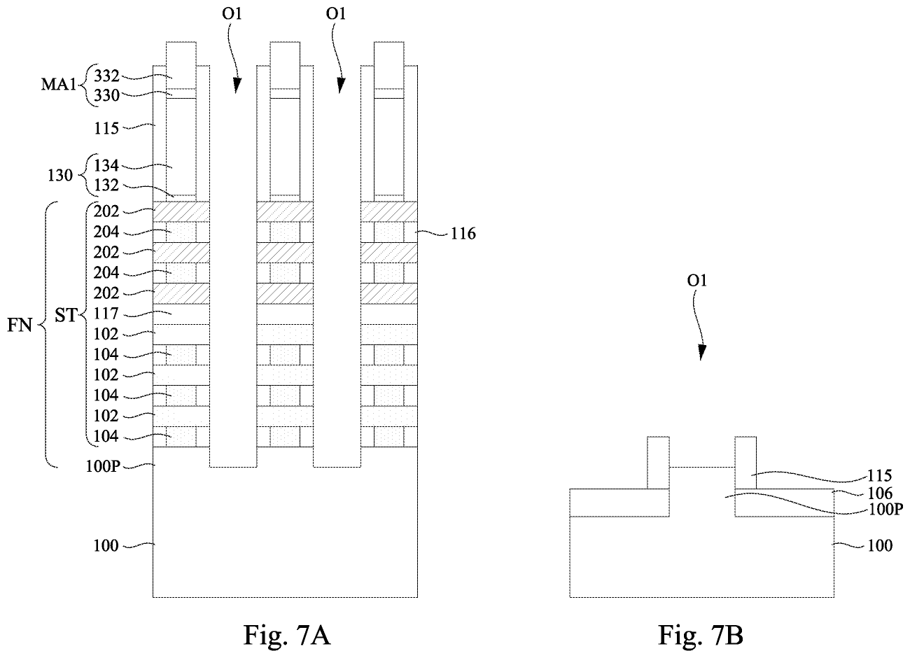

Reference is made to FIGS. 6A and 6B. After the source/drain openings O1 are formed, the semiconductor layers 104 and the semiconductor layers 204 are laterally etched to form sidewall recesses R1. Moreover, the crystalline orientation switching layer 105 is removed to form a gap G1 vertically between the topmost semiconductor layer 102 and the bottommost semiconductor layer 202. In some embodiments, the gap G1 may spatially connect the source/drain openings O1 on opposite sides of the dummy gate structure 130. In this embodiment, the crystalline orientation switching layer 105 is removed and will be replaced with another dielectric material (e.g., the isolation layer 117 in FIG. 7A), so as to provide desired electrical isolation purpose.

In some embodiments, the sidewalls of the semiconductor layers 104 and 204 may be etched using isotropic etching processes, such as wet etching or the like. In some embodiments where the semiconductor layers 104 and 204 include, e.g., SiGe, and the semiconductor layers 102 and 202 include, e.g., Si, an etch process with tetramethylammonium hydroxide (TMAH), ammonium hydroxide (NH₄OH), or the like may be used to etch sidewalls of the semiconductor layers 104 and 204. On the other hand, the crystalline orientation switching layer 105 may be etched using suitable etchant, such as hydrofluoric acid (HF). In some embodiments, a first etching process is performed to etch the semiconductor layers 104 and 204, and a second etching process is performed to etch crystalline orientation switching layer 105. The first etching process may be performed prior to or after the second etching process.

Reference is made to FIGS. 7A and 7B. Inner spacers 116 are formed in the sidewall recesses R1 on opposite ends of each of the semiconductor layers 104 and the semiconductor layers 204, and an isolation layer 117 is formed in the gap G1. In some embodiments, the inner spacers 116 and the isolation layer 117 may include a same material. In some embodiments, the inner spacers 116 and the isolation layer 117 may be formed by, for example, depositing a dielectric layer blanket over the substrate 100 and filling the sidewall recesses R1 and the gap G1, and then performing an anisotropic etching to remove portions of the dielectric layer outside the sidewall recesses R1 and the gap G1, leaving the remaining portions of the dielectric layer in the sidewall recesses R1 and the gap G1 as the inner spacers 116 and the isolation layer 117, respectively. The inner spacers 116 and the isolation layer 117 may be deposited by a conformal deposition process, such as CVD, ALD, or the like. The dielectric layer may include a material such as SiN, SiOCN, SiCN, SIOC, although any suitable material, such as low-dielectric constant (low-k) materials having a k-value less than about 3.5, may be utilized. In some embodiments, void may be formed in the isolation layer 117 due to high aspect ratio.

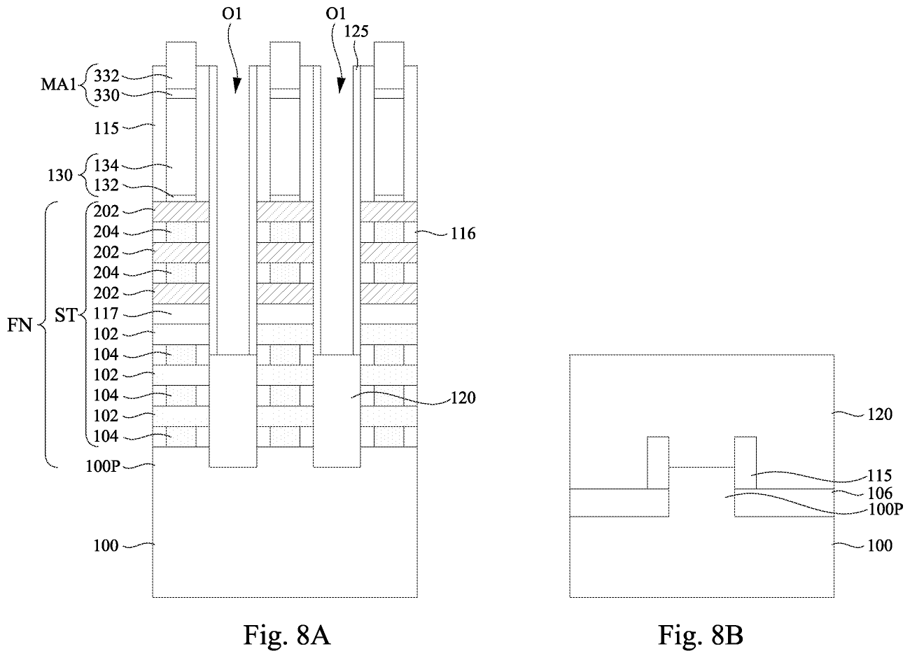

Reference is made to FIGS. 8A and 8B. Dummy materials 120 are formed in the source/drain openings O1. In greater detail, the dummy materials 120 may be formed at lower portions of the source/drain openings O1, such that the top surfaces of the dummy materials 120 may be lower than the bottommost semiconductor layer 202. As a result, the sidewalls of the semiconductor layers 202 may be exposed through the upper portions of the source/drain openings O1 once the dummy materials 120 are formed. In some embodiments, the dummy materials 120 may be formed by, for example, depositing a dielectric material filling the source/drain openings O1, and then etching back the dielectric material to lower the top surface of the dielectric material to a desired position. In some embodiments, the dummy materials 120 may be made of SiOCN, or other suitable material.

Afterwards, liners 125 are formed lining sidewalls of the upper portions of the source/drain openings O1, so as to cover the sidewall surfaces of the semiconductor layers 202 and sidewall surfaces of the isolation layers 117. The liners 125 may also cover the sidewalls of the spacers 115. In some embodiments, the liners 125 may be formed by, for example, depositing a liner layer blanket over the substrate, an anisotropic etching process is performed to remove horizontal portions of the liner layer, such that vertical portions of the liner layer remain on sidewalls of the semiconductor layers 202, the crystalline orientation switching layer 105, and the spacers 115. In some embodiments, the remaining vertical portions of the liner layer can be referred to as the liners 125. In some embodiments, the liners 125 may be made of SiN, metal oxide, or other suitable material.

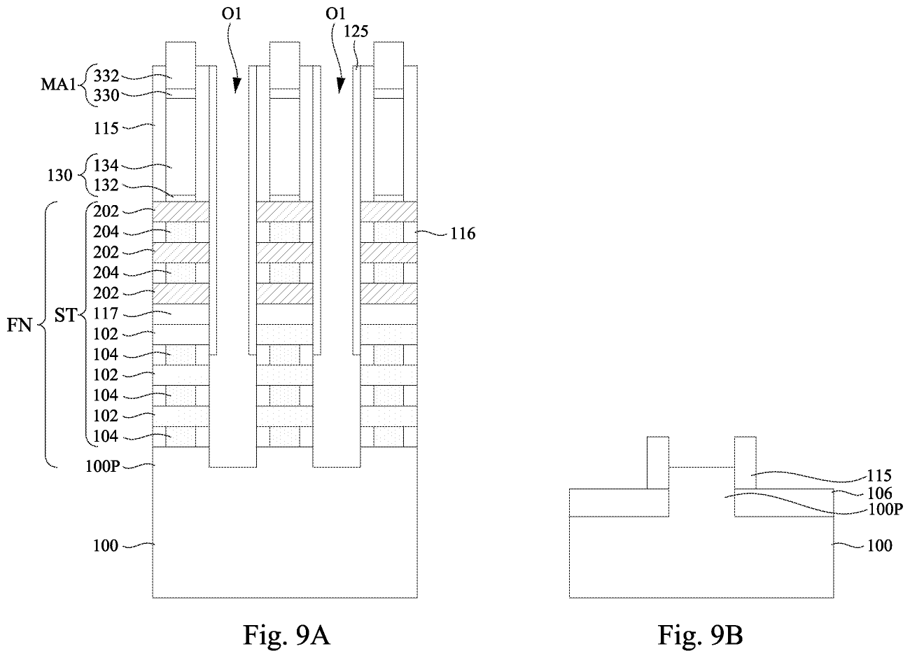

Reference is made to FIGS. 9A and 9B. The dummy materials 120 are removed by suitable etching process, so as to expose the sidewalls of the semiconductor layers 102 through the lower portions of the source/drain openings O1. In some embodiments, the liners 125 may include a higher etching resistance to the etching process than the dummy materials 120, and thus the liners 125 may remain after the dummy materials 120 are removed.

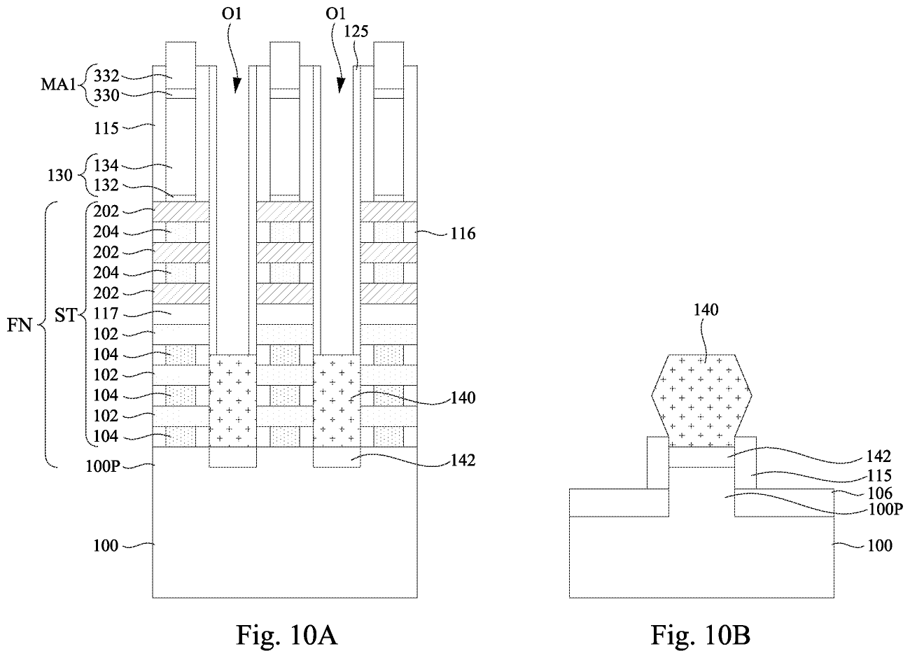

Reference is made to FIGS. 10A and 10B. Epitaxy layers 142 are formed at bottoms of the source/drain openings O1, and then first source/drain epitaxy structures 140 are formed over the epitaxy layers 142, respectively. In some embodiments, the formation of the epitaxy layers 142 may include a plurality of deposition cycles, in which each deposition cycle may include a selective epitaxial growth (SEG) process and an etching process. In some embodiments, the SEG process may selectively grow a semiconductor material on exposed semiconductor surfaces, such as the exposed surfaces of the semiconductor strips 100P and the exposed surfaces of the semiconductor layers 102. However, because the exposed areas of the semiconductor strips 100P are greater than the exposed area of each of the semiconductor layers 102, the semiconductor material may include higher growing rate on the exposed areas of the semiconductor strips 100P than on the exposed area of each of the semiconductor layers 102. That is, a greater amount of the semiconductor material will be grown on the exposed areas of the semiconductor strips 100P than on the exposed area of each of the semiconductor layers 102. As a result, the etching process in each deposition cycle of the epitaxy layers 142 may remove portions of the semiconductor material formed on the exposed area of each of the semiconductor layers 102, while portions of the semiconductor material may remain over the semiconductor strips 100P after the etching process. Accordingly, performing several deposition cycles may allow a bottom-up deposition for the epitaxy layers 142. That is, the epitaxy layers 142 may be formed from the bottoms of the source/drain openings O1 via a bottom-up manner.

The first source/drain epitaxy structures 140 may be formed by suitable deposition process, such as a selective epitaxial growth (SEG) process. In some embodiments, the SEG process may selectively grow a semiconductor material on exposed semiconductor surfaces, such as the exposed surfaces of the epitaxy layers 142 and the exposed surfaces of the semiconductor layers 102. In some embodiments, an implantation process may be performed to the first source/drain epitaxy structures 140. For example, when the semiconductor layers 102 have (100) crystalline orientation, the first source/drain epitaxy structures 140 may be doped with n-type dopants, such as phosphorus (P), arsenic (As), or antimony (Sb), or the like. Alternatively, when the semiconductor layers 102 have (110) crystalline orientation, the first source/drain epitaxy structures 140 may be doped with p-type dopants, such as boron (B), gallium (Ga), indium (In), aluminium (Al), or the like. In some embodiments, each of the first source/drain epitaxy structures 140 may include different layers (e.g., L1, L2 . . . etc), in which the layers may include different dopant concentrations. In some embodiments, the epitaxy layers 142 may be formed without performing an implantation process, and thus the epitaxy layers 142 are un-doped.

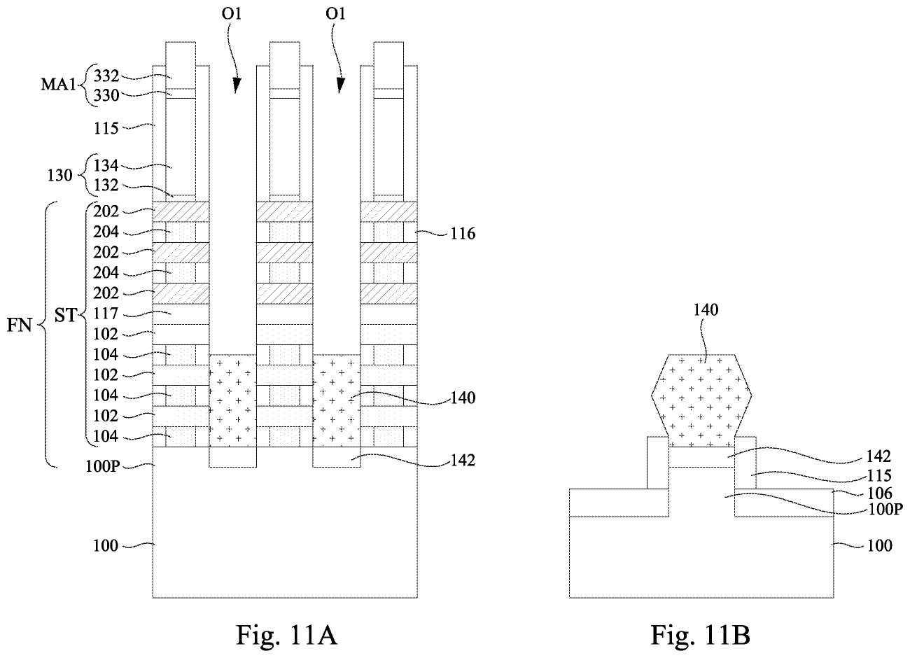

Reference is made to FIGS. 11A and 11B. After the first source/drain epitaxy structures 140 are formed, the liners 125 are removed through suitable etching process. After the liners 125 are removed, the sidewalls of the semiconductor layers 202 and are exposed.

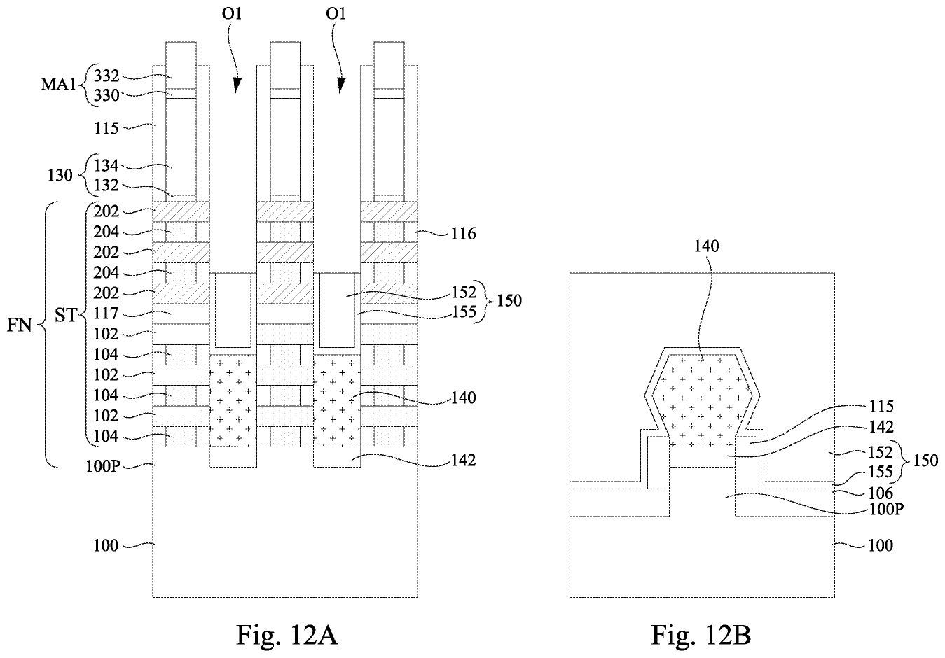

Reference is made to FIGS. 12A and 12B. A contact etch stop layer (CESL) 155 is formed covering the first source/drain epitaxy structures 140. Afterwards, an interlayer dielectric (ILD) layer 152 is formed over the CESL 155. Then, an etching back process is performed to lower top surfaces of the CESL 155 and the ILD layer 152, such that sidewalls of the semiconductor layers 202 are exposed through the source/drain openings O1. In some embodiments, the CESL 155 and the ILD layer 152 can be collectively referred to as an isolation structure 150. In some embodiments, the topmost semiconductor layer 102, the isolation layer 107, and the bottommost semiconductor layer 202 are in contact with the CESL 155 of the isolation structure 150.

In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 155 and the ILD layer 152 can be formed using, for example, CVD, ALD or other suitable techniques.

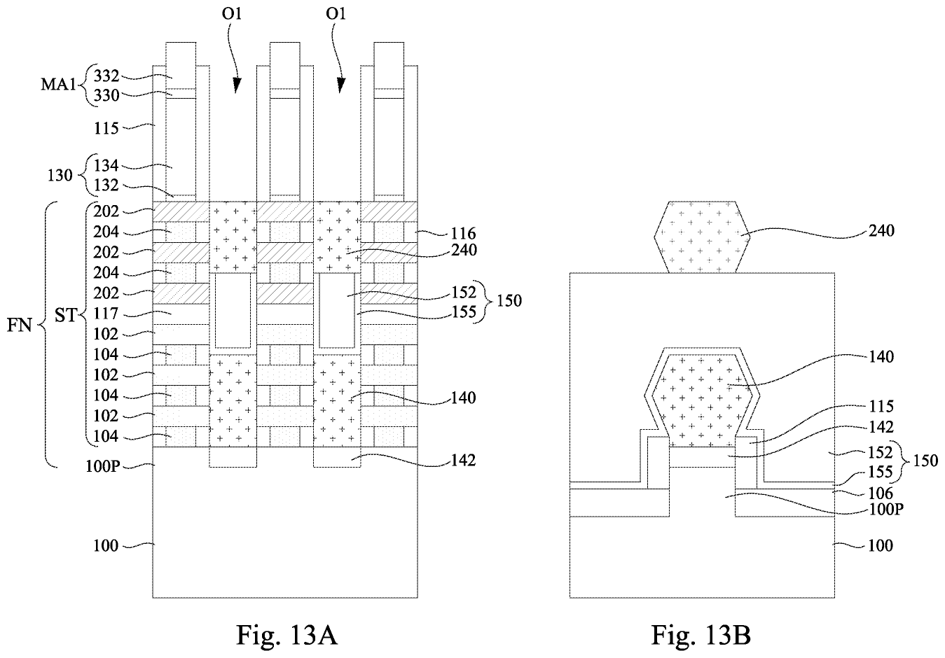

Reference is made to FIGS. 13A and 13B. Second source/drain epitaxy structures 240 are formed on opposite ends of each of the semiconductor layers 202. In some embodiments, the second source/drain epitaxy structures 240 may be formed by a selective epitaxial growth (SEG) process. The SEG process may selectively grow a semiconductor material on exposed semiconductor surfaces, such as the exposed surfaces of the semiconductor layers 202. In some embodiments, an implantation process may be performed to the second source/drain epitaxy structures 240. For example, when the semiconductor layers 202 have (100) crystalline orientation, the second source/drain epitaxy structures 240 may be doped with n-type dopants, such as phosphorus (P), arsenic (As), or antimony (Sb), or the like. Alternatively, when the semiconductor layers 202 have (110) crystalline orientation, the second source/drain epitaxy structures 240 may be doped with p-type dopants, such as boron (B), gallium (Ga), indium (In), aluminium (Al), or the like. In some embodiments, each of the second source/drain epitaxy structures 240 may include different layers (e.g., L1, L2 . . . etc), in which the layers may include different dopant concentrations. In some embodiments, the first source/drain epitaxy structures 140 and the second source/drain epitaxy structures 240 may include dopants with opposite conductivity types. For example, if the first source/drain epitaxy structures 140 are doped with n-type dopants, the second source/drain epitaxy structures 240 are doped with p-type dopants. Similarly, if the first source/drain epitaxy structures 140 are doped with p-type dopants, the second source/drain epitaxy structures 240 are doped with n-type dopants. In the cross-sectional view of FIG. 13B, the second source/drain epitaxy structure 240 may include different widths than the first source/drain epitaxy structure 140. In some embodiments, the topmost semiconductor layer 102, the isolation layer 107, and the bottommost semiconductor layer 202 are in contact with the isolation structure 150. However, in other embodiments, the isolation layer 107 and the bottommost semiconductor layer 202 are in contact with the isolation structure 150, while the topmost semiconductor layer 102 may be in contact with the first source/drain epitaxy structures 140, such that one first source/drain epitaxy structure 140 may be in contact with three semiconductor layers 102 and one second source/drain epitaxy structure 240 may be in contact with two semiconductor layers 202. In yet other embodiments, the topmost semiconductor layer 102 and the isolation layer 107 are in contact with the isolation structure 150, while the bottommost semiconductor layer 202 may be in contact with the second source/drain epitaxy structures 240, such that one first source/drain epitaxy structure 140 may be in contact with two semiconductor layers 102 and one second source/drain epitaxy structure 240 may be in contact with three semiconductor layers 202.

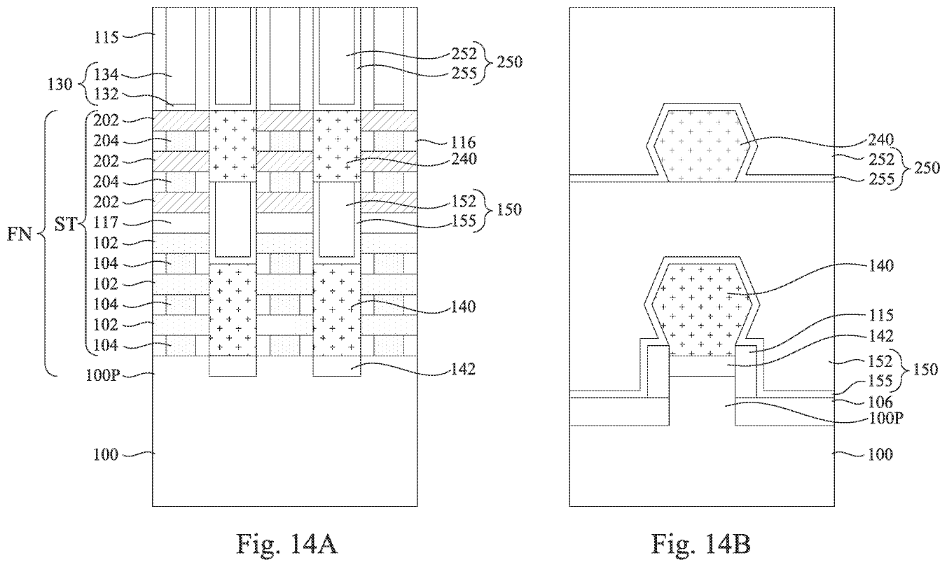

Reference is made to FIGS. 14A and 14B. A contact etch stop layer (CESL) 255 is formed covering the second source/drain epitaxy structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structures 130 are exposed. In some embodiments, the patterned masks MA1 are removed during the planarization process. In some embodiments, the CESL 255 and the ILD layer 252 can be collectively referred to as an isolation structure 250. The materials of the CESL 255 and the ILD layer 252 may be similar to the materials of the CESL 155 and the ILD layer 152, respectively, and thus relevant details will not be repeated for brevity. In some embodiments, the isolation structures 150 and 250 may collectively form a composite isolation structure.

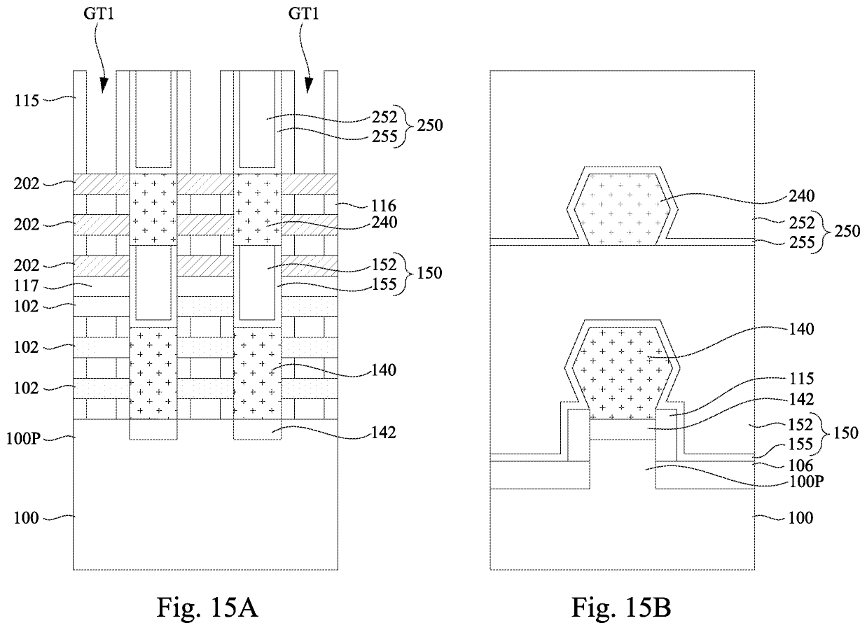

Reference is made to FIGS. 15A and 15B. The dummy gate structures 130 are removed to form gate trenches GT1 between each pair of the spacers 115. Then, an etching process is performed to remove the semiconductor layers 104 and 204 through the gate trenches GT1, such that that the semiconductor layers 102 and the semiconductor layers 202 are suspended over the substrate 100.

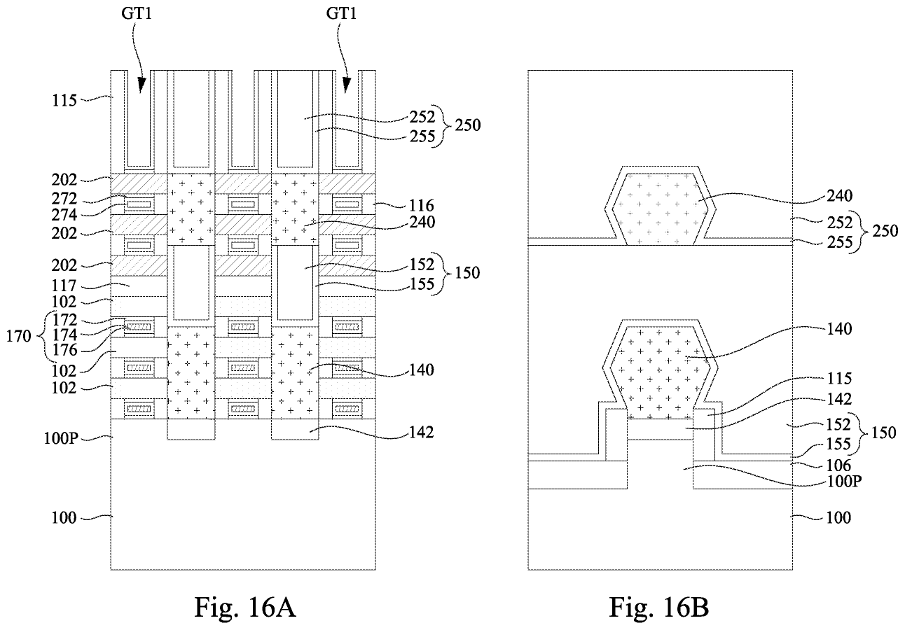

Reference is made to FIGS. 16A and 16B. Interfacial layers 172 and 272 are formed on exposed surfaces of the semiconductor layers 102 and 202, respectively. Then, gate dielectric layers 174 and 274 are formed over the interfacial layers 172 and 272, respectively. In some embodiments, the interfacial layers 172 and 272 may be formed using a same deposition process, and the gate dielectric layers 174 and 274 may be formed using a same deposition process.

After the interfacial layers 172 and 272 and the gate dielectric layers 174 and 274 are formed, gate electrodes 176 are formed in the gate trenches GT1 and over the gate dielectric layers 174. The gate electrodes 176 are then etched back, such that the remaining gate electrodes 176 are at the lower portion of the gate trenches GT1. Accordingly, first metal gate structures 170 are formed. In greater detail, the first metal gate structures 170 are formed in bottom portions of the gate trenches GT1, such that the first metal gate structures 170 may wrap around the respective semiconductor layers 102. In some embodiments, each of the first metal gate structures 170 may include the interfacial layer 172, the gate dielectric layer 174 over the interfacial layer 172, and the gate electrode 176 over the gate dielectric layer 174.

In some embodiments, the interfacial layers 172 and 272 may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 176 may include work function metal layer(s) and a filling metal. The work function metal layer may be an n-type or p-type work function layer. Exemplary p-type work function metals include TIN, TaN, Ru, Mo, Al, WN, ZrSi₂, MoSi₂, TaSi₂, NiSi₂, WN, other suitable p-type work function materials, or combinations thereof. Exemplary n-type work function metals include Ti, Ag, TaAl, TaAlC, TiAlN, TaC, TaCN, TaSiN, Mn, Zr, other suitable n-type work function materials, or combinations thereof. The work function layer may include a plurality of layers. The filling metal may include tungsten (W), aluminum (Al), copper (Cu), or another suitable conductive material(s).

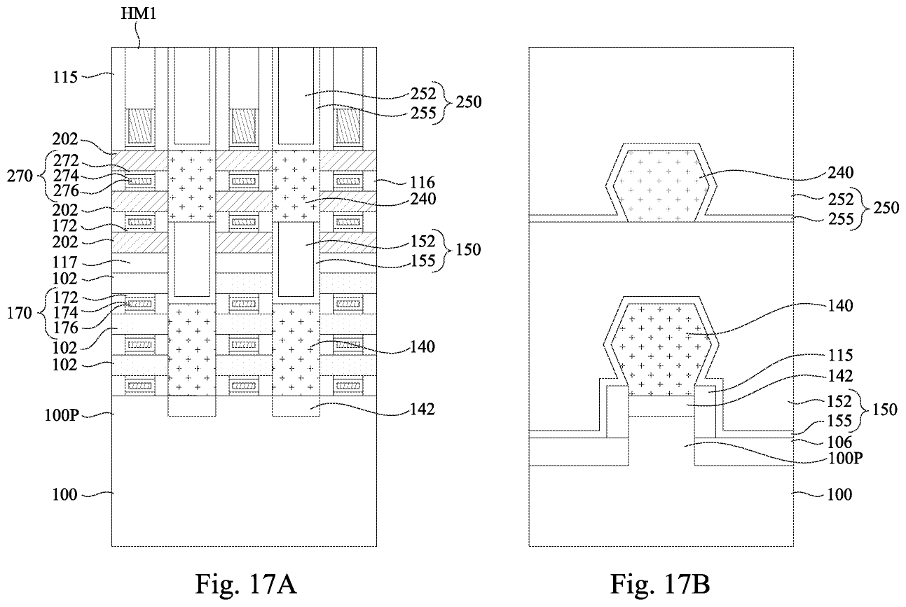

Reference is made to FIGS. 17A and 17B. Gate electrodes 276 are formed in the gate trenches GT1 and over the first metal gate structures 170. Accordingly, second metal gate structures 270 are formed. In greater detail, the second metal gate structures 270 are formed in upper portions of the gate trenches GT1 and above the first metal gate structures 170, such that the second metal gate structures 270 may wrap around the respective semiconductor layers 202. In some embodiments, each of the second metal gate structures 270 may include the interfacial layer 272, the gate dielectric layer 274 over the interfacial layer 272, and the gate electrode 276 over the gate dielectric layer 274. The materials of the gate electrode 276 may be similar to those described with respect to the gate electrode 176, and thus relevant details will not be repeated for brevity.

The second metal gate structures 270 are then etched back, such that top surfaces of the second metal gate structures 270 are lower than top surfaces of the gate spacers 115. Afterwards, hard masks HM1 are formed over the respectively second metal gate structures 270. In some embodiments, the hard masks HM1 may include one or more layers of dielectric material such as silicon nitride based material including SiN, SiCN and SiOCN. The hard masks HM1 may be formed by, for example, depositing a dielectric layer over the etched back second metal gate structures 270, and then performing a planarization process, such as CMP, on the dielectric layer until the isolation structures 250 are exposed.

The first metal gate structure 170, the first source/drain epitaxy structures 140 on opposite sides of the first metal gate structure 170, and the semiconductor layers 102 that are in contact with the first source/drain epitaxy structures 140 may collectively serve as the first transistor TR1 as described in FIG. 1. In such condition, the semiconductor layers 102 that are in contact with the first source/drain epitaxy structures 140 may also be referred to as channel layers of the first transistor TR1. Similarly, the second metal gate structure 270, the second source/drain epitaxy structures 240 on opposite sides of the second metal gate structure 270, and the semiconductor layers 202 that are in contact with the second source/drain epitaxy structures 240 may collectively serve as the second transistor TR2 as described in FIG. 1. In such condition, the semiconductor layers 202 that are in contact with the second source/drain epitaxy structures 240 may also be referred to as channel layers of the second transistor TR2. In FIG. 17A, opposite ends of the topmost semiconductor layer 102 are in contact with the isolation structures 150, and are not in contact with the first source/drain epitaxy structures 140. Thus, the topmost semiconductor layer 102 may not function as a channel layer of the first transistor TR1. Similarly, opposite ends of the bottommost semiconductor layer 202 are in contact with the isolation structure 150, and are not in contact with the second source/drain epitaxy structures 240. Thus, the topmost bottommost semiconductor layer 202 may not function as a channel layer of the second transistor TR2.

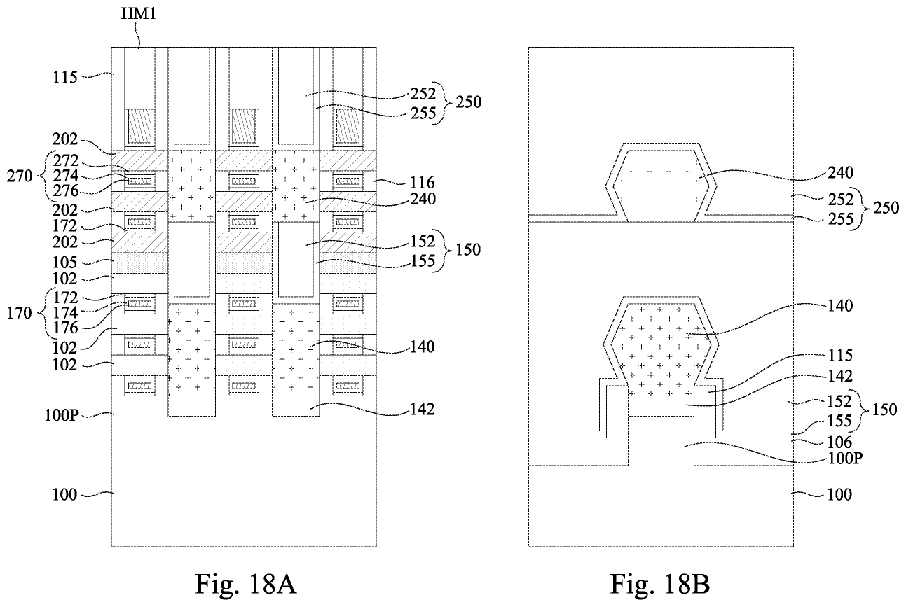

FIGS. 18A and 18B illustrate a semiconductor device in accordance with some embodiments of the present disclosure. It is noted that FIG. 18A has a same cross-sectional view as FIGS. 2A to 17A, and FIG. 18B has a same cross-sectional view as FIGS. 2B to 17B. It is noted that some elements described in FIGS. 18A to 18B may be similar to those described with respect to FIGS. 2A to 17B, such elements are labeled the same, and relevant details will not be repeated for brevity.

The difference between the embodiments of FIGS. 18A and 18B and the embodiments of FIGS. 2A to 17B is that the crystalline orientation switching layer 105 is not removed during the process as discussed in FIGS. 6A and 6B, and thus the crystalline orientation switching layer 105 may remain in the final structure. This is because the crystalline orientation switching layer 105 is made of a dielectric layer, such as metal oxide, that is different from the semiconductor materials of the semiconductor layer 102,104, 202, and 205. The crystalline orientation switching layer 105 may provide sufficient etching selectivity to the semiconductor materials of the semiconductor layer 102, 104, 202, and 205.

As shown in FIG. 18A, sidewalls of the crystalline orientation switching layer 105 may be in contact with the isolation structures 150. In some embodiments, the crystalline orientation switching layer 105 may be in contact with the CESL 255, and may be separated from the ILD layer 252 through the CESL 255. Moreover, the topmost semiconductor layer 102 may be in contact with the bottom surface of the crystalline orientation switching layer 105, and the bottommost semiconductor layer 202 may be in contact with the top surface of the crystalline orientation switching layer 105.

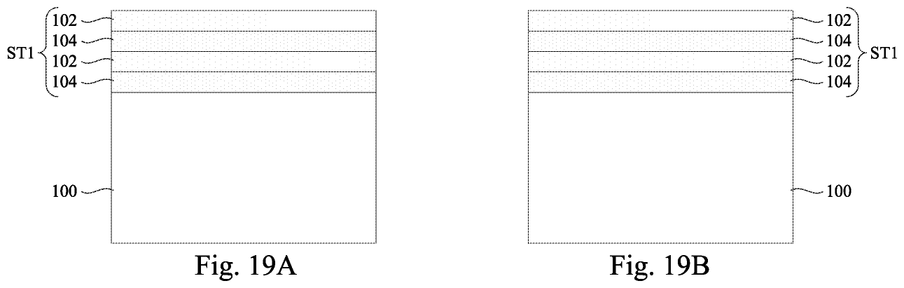

FIGS. 19A to 35B illustrate a method in various stages of forming a semiconductor device in accordance with some embodiments of the present disclosure. It is noted that FIGS. 19A, 20A, 21A, 22A, 23A, 24A, 25A, 26, 27A, 28A, 29A, 30A, 31A, 32A, 33A, 34A, and 35A include a same cross-sectional view as FIGS. 2A to 17A, and FIGS. 19B, 20B, 21B, 22B, 23B, 24B, 25B, 27B, 28B, 29B, 30B, 31B, 32B, 33B, 34B, and 35B include a same cross-sectional view as FIGS. 2B to 17B. Although FIGS. 19A to 35B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements and some processes of FIGS. 19A to 35B may be similar to those described with respect to FIG. 1 and FIGS. 19A to 35B, and thus relevant details will not be repeated for brevity.

Reference is made to FIGS. 19A and 19B. Shown there is a substrate 100. Then, a first stack ST1 of alternating semiconductor layers 102 and semiconductor layers 104 is formed over a substrate 100. In some embodiments, the substrate 100 may include a first crystalline orientation. For example, the first crystalline orientation may be (100) crystalline orientation or (110) crystalline orientation. The semiconductor layers 102 and 104 are alternately deposited over the substrate 100. Due to the nature of epitaxial growth, the semiconductor layers 102 and 104 tend to have a same crystalline orientation as the substrate 100. Thus, the semiconductor layers 102 and 104 may also include a first crystalline orientation.

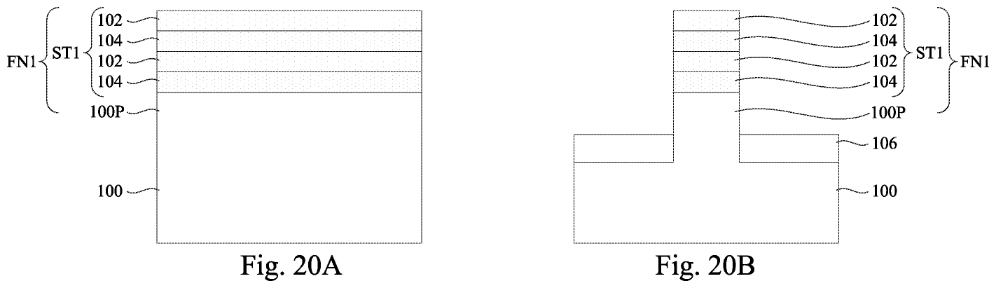

Reference is made to FIGS. 20A and 20B. A patterning process is performed to the first stack ST1 and the substrate 100 to form a fin structure FN1. The fin structure FN1 may include a remaining portion of the first stack ST1 and a semiconductor strip 100P protruding over the substrate 100. After the fin structure FN1 is formed, isolation structures 106 are formed over the substrate 100 and laterally surrounding the fin structure FN1.

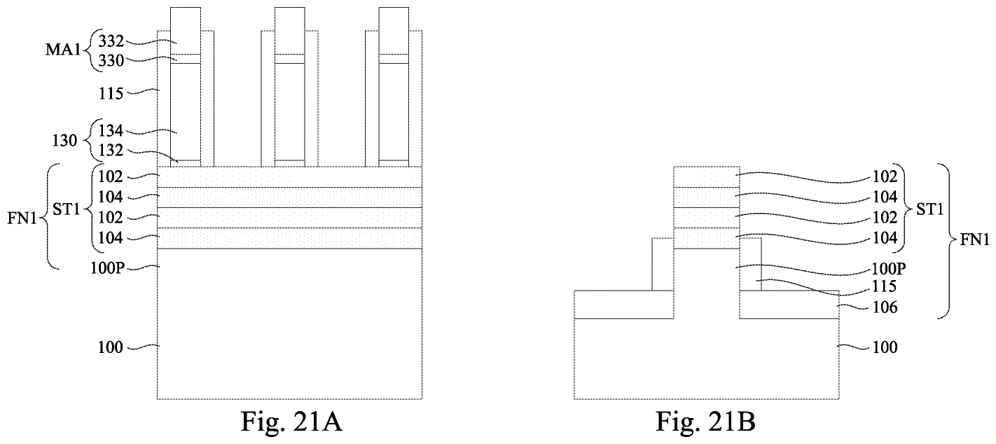

Reference is made to FIGS. 21A and 21B. Dummy gate structures 130 are formed over the substrate 100 and crossing the fin structure FN1. In some embodiments, patterned masks MA1 are used for forming the dummy gate structures 130 as described above. Spacers 115 are formed on opposite sidewalls of each of the dummy gate structures 130 (see FIG. 21A), and on opposite sidewalls of the fin structure FN1 (see FIG. 21B). In some embodiments, portions of the spacers 115 on opposite sidewalls of each of the dummy gate structures 130 can be referred to as gate spacers, and portions of the spacers 115 on opposite sidewalls of the fin structure FN1 can be referred to as fin spacers.

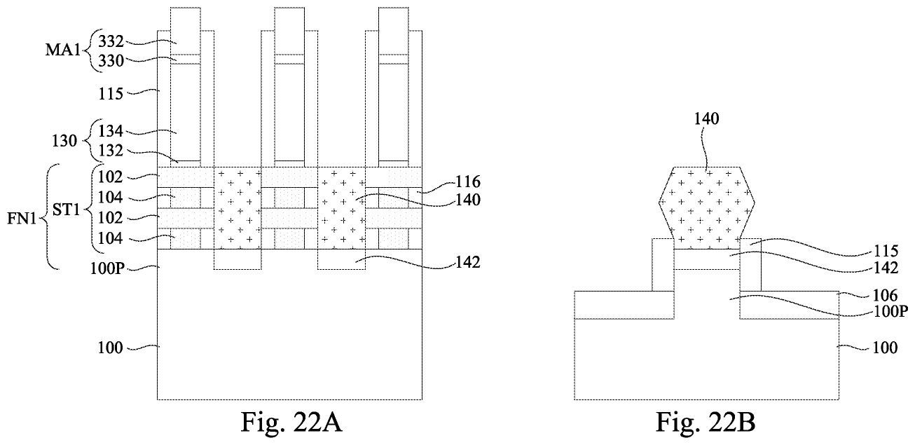

Reference is made to FIGS. 22A and 22B. An etching process is performed to remove portions of the fin structure FN1 (or stack ST1) by using the dummy gate structures 130 and the spacers 115 as etch mask, so as to form source/drain openings. Then, the semiconductor layers 104 are laterally etched to form sidewall recesses, and inner spacers 116 are formed in the sidewall recesses on opposite ends of each of the semiconductor layers 104. Afterwards, epitaxy layers 142 are formed at bottoms of the source/drain openings O1, and then first source/drain epitaxy structures 140 are formed over the epitaxy layers 142, respectively. The materials and the formation methods of the inner spacers 116, the epitaxy layers 142, and the first source/drain epitaxy structures 140 have been described above, and relevant details will not be repeated.

In some embodiments, an implantation process may be performed to the first source/drain epitaxy structures 140. For example, when the semiconductor layers 102 have (100) crystalline orientation, the first source/drain epitaxy structures 140 may be doped with n-type dopants, such as phosphorus (P), arsenic (As), or antimony (Sb), or the like. Alternatively, when the semiconductor layers 102 have (110) crystalline orientation, the first source/drain epitaxy structures 140 may be doped with p-type dopants, such as boron (B), gallium (Ga), indium (In), aluminium (Al), or the like.

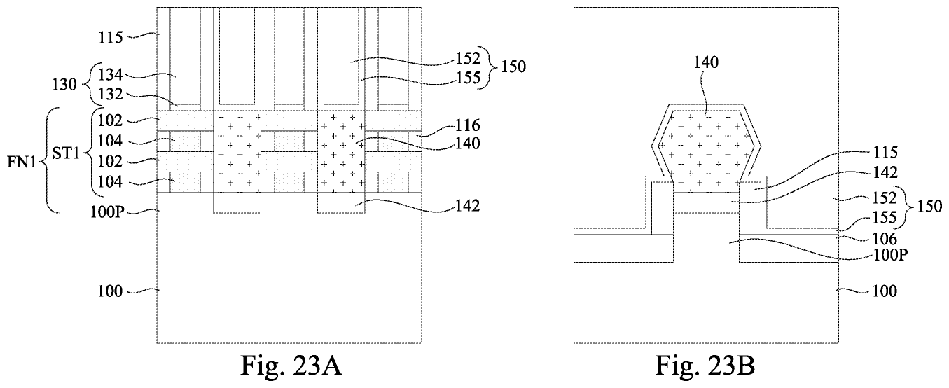

Reference is made to FIGS. 23A and 23B. A contact etch stop layer (CESL) 155 is formed covering the first source/drain epitaxy structures 140. Afterwards, an interlayer dielectric (ILD) layer 152 is formed over the CESL 155. Then, a planarization process, such as CMP, is performed to the ILD layer 152 and the CESL 155 until the dummy gate structures 130 are exposed. In some embodiments, the CESL 155 and the ILD layer 152 can be collectively referred to as an isolation structure 150.

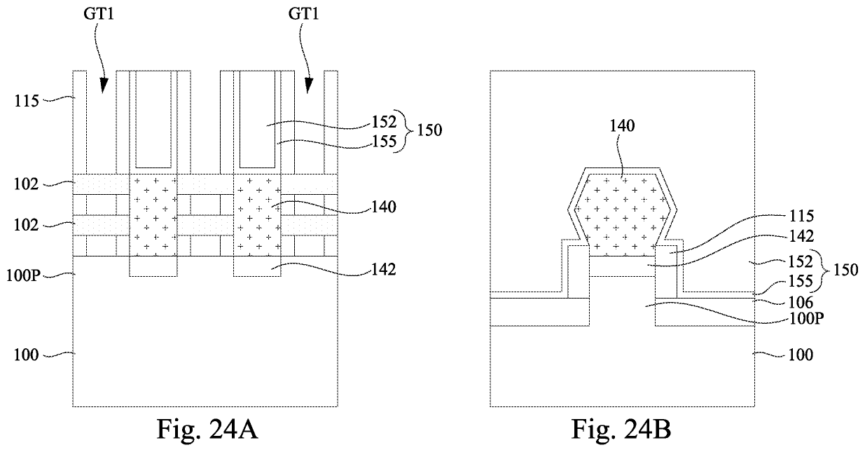

Reference is made to FIGS. 24A and 24B. The dummy gate structures 130 are removed to form gate trenches GT1 between each pair of the spacers 115. Then, an etching process is performed to remove the semiconductor layers 104 through the gate trenches GT1, such that that the semiconductor layers 102 are suspended over the substrate 100.

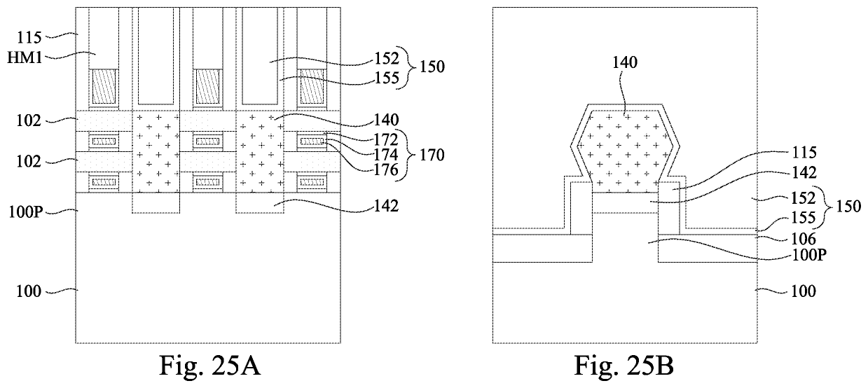

Reference is made to FIGS. 25A and 25B. Interfacial layers 172 are formed on exposed surfaces of the semiconductor layers 102, respectively. Afterwards, gate dielectric layers 174 are formed over the interfacial layers 172, and gate electrodes 176 are formed over the gate dielectric layers 174. Accordingly, first metal gate structures 170 are formed, in which each of the first metal gate structures 170 includes an interfacial layer 172, a gate dielectric layer 174, and a gate electrode 176. A planarization process, such as CMP, is performed to remove the excess gate dielectric layers 174 and the excess gate electrodes 176 until the isolation structures 150 are exposed.

The first metal gate structures 170 are then etched back, such that top surfaces of the first metal gate structures 170 are lower than top surfaces of the spacers 115. Afterwards, hard masks HM1 are formed over the respectively first metal gate structures 170. The hard masks HM1 may be formed by, for example, depositing a dielectric layer over the etched back first metal gate structures 170, and then performing a planarization process, such as CMP, on the dielectric layer until the isolation structure 150 is exposed.

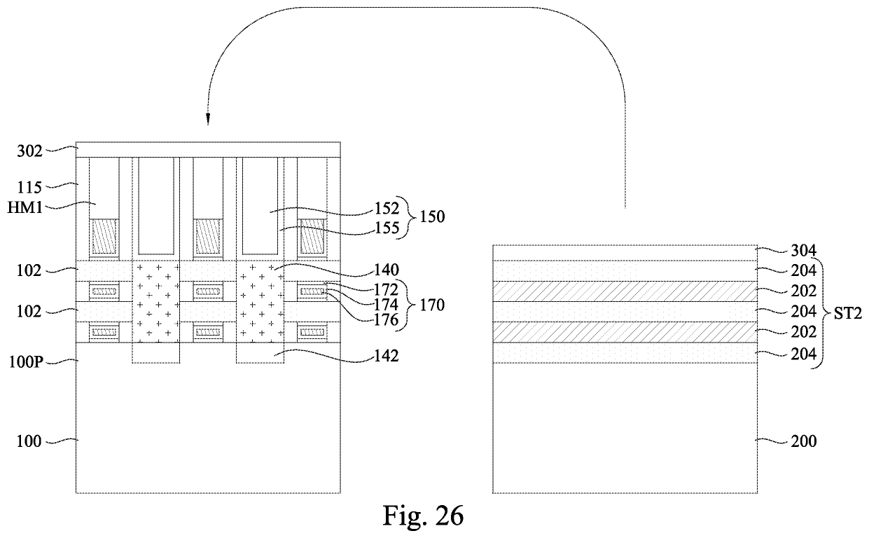

Reference is made to FIG. 26. A bonding layer 302 is formed over the structure shown in FIGS. 25A and 25B. In greater detail, the bonding layer 302 may be in contact with the hard masks HM1, the spacers 115, and the isolation structures 150. In some embodiments, the bonding layer 302 may be deposited over the structure shown in FIGS. 25A and 25B using suitable deposition process, such as CVD, PVD, ALD, or the like.

On the other hand, a substrate 200 is provided. The substrate 200 may include a similar material as the substrate 100. For example, the substrate 200 may be made of silicon. A second stack ST2 of alternating semiconductor layers 202 and semiconductor layers 204 are formed over the substrate 200.

In some embodiments, the substrate 200 may include a second crystalline orientation that is different from the first crystalline orientation of the substrate 100. For example, if the first crystalline orientation is (100) crystalline orientation, the second crystalline orientation is (110) crystalline orientation. Similarly, if the first crystalline orientation is (110) crystalline orientation, the second crystalline orientation is (100) crystalline orientation. The semiconductor layers 202 and 204 are alternately deposited over the substrate 200. Due to the nature of epitaxial growth, the semiconductor layers 202 and 204 tend to have a same crystalline orientation as the substrate 200. Thus, the semiconductor layers 202 and 204 may also include a second crystalline orientation.

A bonding layer 304 is formed over the second stack ST2. In some embodiments, the bonding layer 304 is in contact with the topmost semiconductor layer 204. The bonding layers 302 and 304 may include dielectric material such as silicon oxide (SiOₓ), silicon dioxide (SiO₂), or other suitable materials. In some embodiments, the bonding layers 302 and 304 may include a same bonding material. In other embodiments, the bonding layers 302 and 304 may include different bonding materials.

The substrate 100 will be bonded to the substrate 200 as indicated by the arrow shown in FIG. 26. In greater detail, the substrate 100 will be bonded to the substrate 200 through the bonding layers 302 and 304, which will be discussed later.

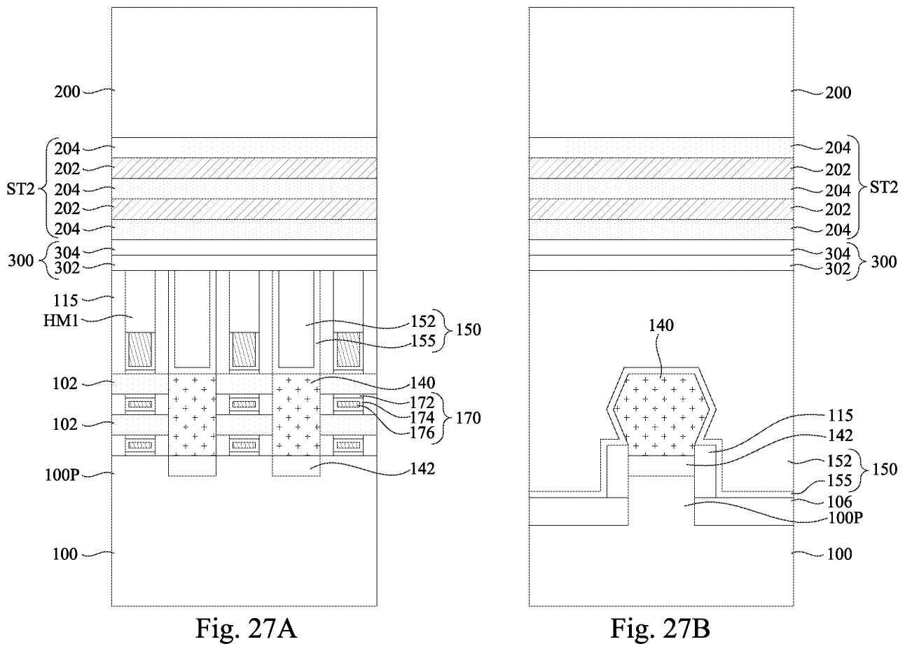

Reference is made to FIGS. 27A and 27B. The substrate 100 is bonded to the substrate 200. For example, in FIGS. 27A and 27B, the substrate 200 is flipped over by 180 degrees, such that the bonding layer 304 on the substrate 200 faces the bonding layer 302 on the substrate 100.

Then, the bonding layers 302 and 304 are bonded with each other using a suitable technique. In some embodiments, the bonding process may further include applying surface treatments to the surfaces of the bonding layers 302 and 304, respectively. The surface treatment may include a plasma treatment. The plasma treatment may be performed in a vacuum environment. After the plasma treatment, the surface treatment may further include a cleaning process (e.g., a rinse with deionized water, or the like) that may be applied to the bonding layers 302 and 304. The bonding layers 302 and 304 are pressed against each other to initiate a pre-bonding of the substrates 100 and 200. The pre-bonding may be performed at room temperature (between about 21 degrees and about 25 degrees). After the pre-bonding, an annealing process may be applied to the bonding layers 302 and 304 that have already been pressed against each other. The annealing process results in an increased bonding force between the bonding layers 302 and 304, such that even if the bonding layers 302 and 304 are no longer subjected to the pressing force, they will not delaminate or peel from each other. In some embodiments, the bonding layers 302 and 304 can be collectively referred to as a bonding structure 300. In some embodiments, the bonding layers 302 and 304 each can be referred to as dielectric layer or isolation layer, and the bonding structure 300 can be referred to as dielectric structure or an isolation structure.

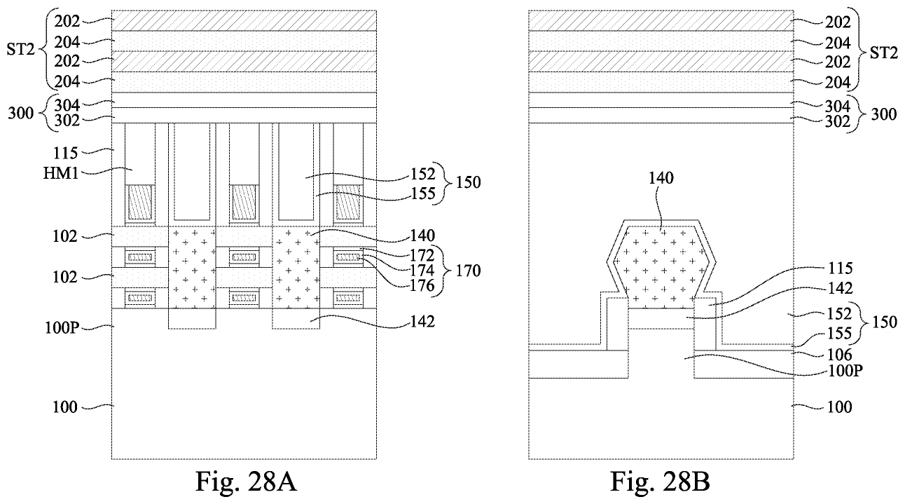

Reference is made to FIGS. 28A and 28B. A grinding process is performed on the backside of the substrate 200 (see FIGS. 27A and 27B), so as to remove the substrate 200 until the topmost semiconductor layer 202 is exposed.

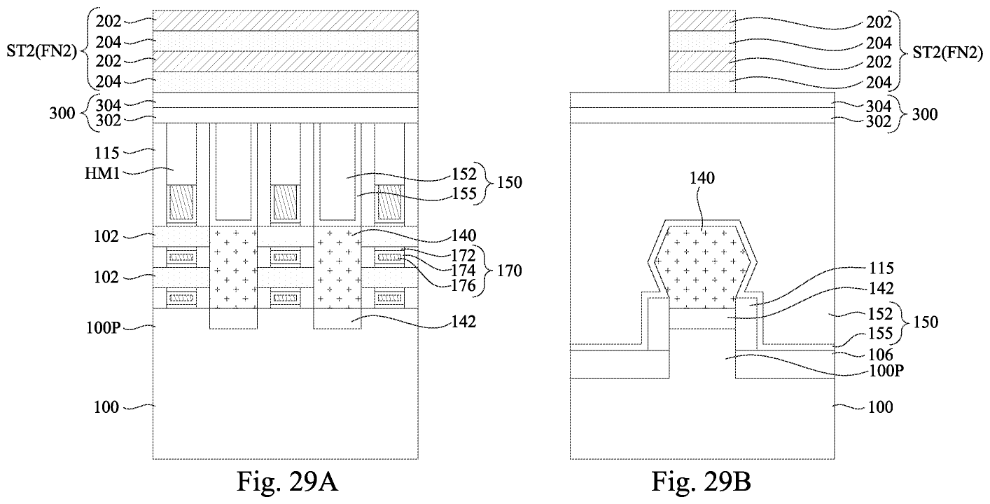

Reference is made to FIGS. 29A and 29B. A patterning process is performed to the second stack ST2 to form a fin structure FN2. In some embodiments, the patterning process may include forming a patterned photoresist layer over the second stack ST2, and then performing an etching process to remove unwanted portions of the second stack ST2 exposed by the patterned photoresist layer. The fin structure FN2 may include a remaining portion of the second stack ST2.

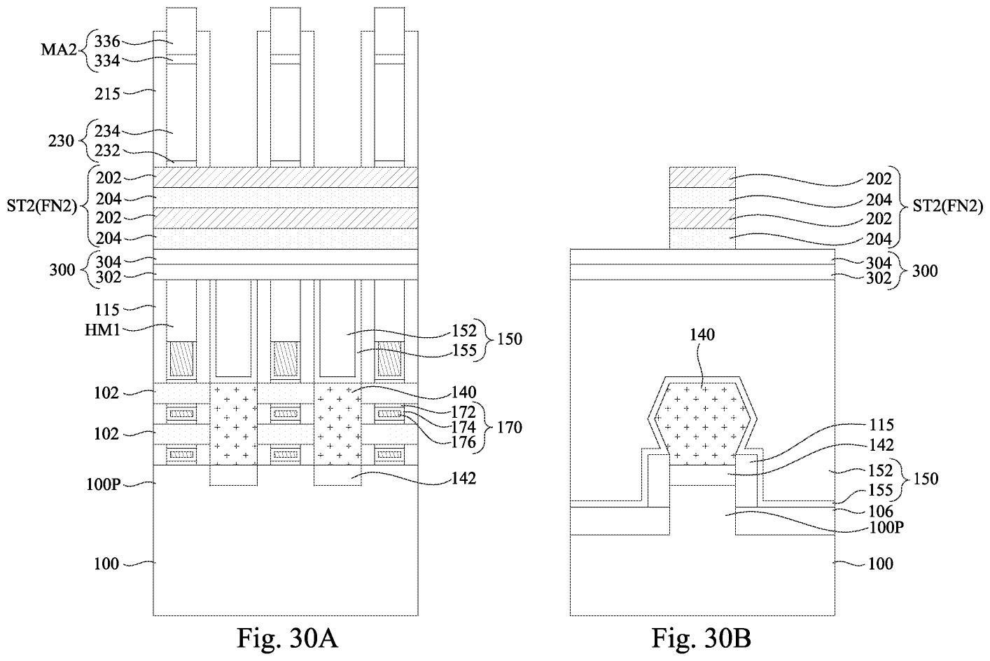

Reference is made to FIGS. 30A and 30B. Dummy gate structures 230 are formed crossing the fin structure FN2. In some embodiments, each of the dummy gate structures 230 includes a dummy gate dielectric 232 and a dummy gate electrode 234 over the dummy gate dielectric 232. The materials of the dummy gate dielectric 232 and the dummy gate electrode 234 may be similar to the materials of the dummy gate dielectric 132 and the dummy gate electrode 134, and thus relevant details will not be repeated.

The dummy gate electrode 234 and the dummy gate dielectric 232 may be formed by, for example, depositing a dummy dielectric layer and a dummy gate layer over the fin structure FN2, forming patterned masks MA2 over the dummy gate layer, and then performing an etching process to the dummy dielectric layer and the dummy gate layer by using the patterned masks MA2 as etch mask. In some embodiments, each of the patterned masks MA2 includes a first hard mask 334 and a second hard mask 336 over the first hard mask 334. In some embodiments, the first hard mask 334 may be formed of silicon nitride, and the second hard mask 336 may be formed of silicon oxide.

Spacers 215 are formed on opposite sidewalls of each of the dummy gate structures 230. The material and the formation method of the spacers 215 may be similar to those described with respect to the spacers 115, and thus relevant details will not be repeated.

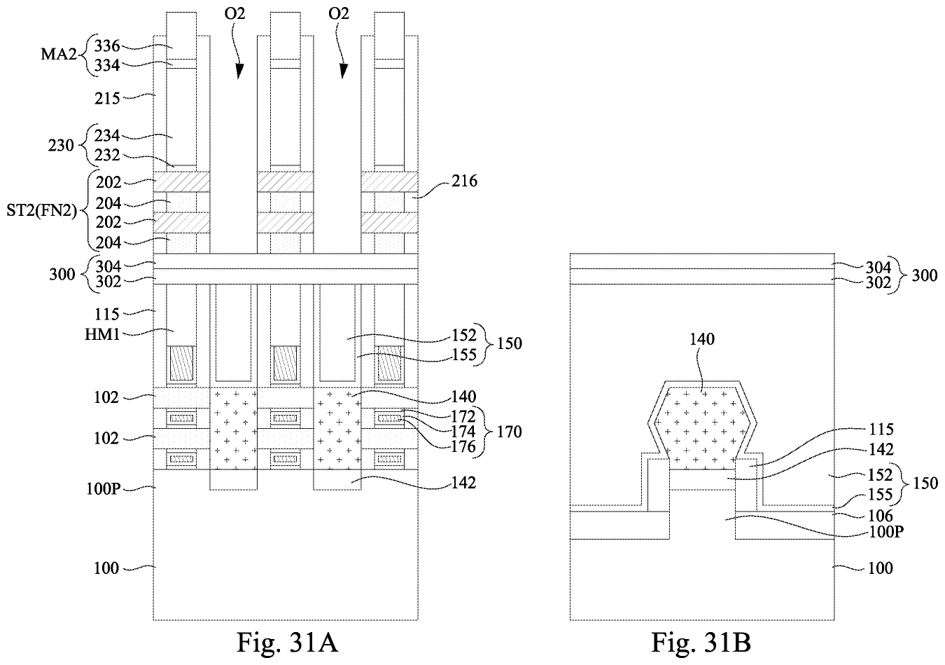

Reference is made to FIGS. 31A and 31B. An etching process is performed to remove portions of the fin structure FN2 (or second stack ST2) by using the dummy gate structures 230 and the spacers 215 as etch mask, so as to form source/drain openings O2. Then, the semiconductor layers 204 are laterally etched to form sidewall recesses, and inner spacers 216 are formed in the sidewall recesses opposite ends of each of the semiconductor layers 204.

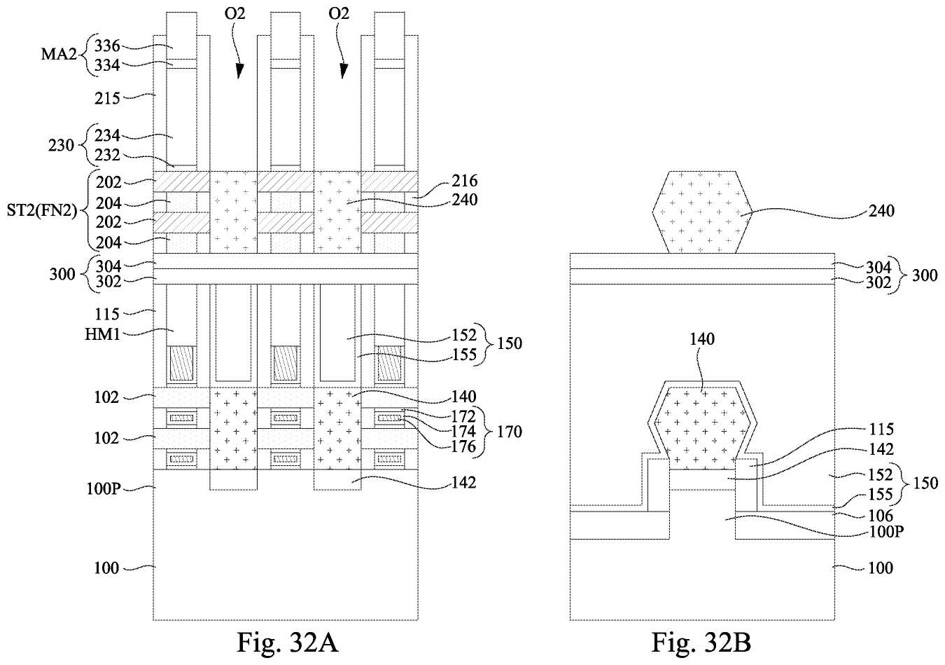

Reference is made to FIGS. 32A and 32B. Second source/drain epitaxy structures 240 are formed on opposite ends of each of the semiconductor layers 202. In some embodiments, an implantation process may be performed to the second source/drain epitaxy structures 240. For example, when the semiconductor layers 202 have (100) crystalline orientation, the second source/drain epitaxy structures 240 may be doped with n-type dopants, such as phosphorus (P), arsenic (As), or antimony (Sb), or the like. Alternatively, when the semiconductor layers 202 have (110) crystalline orientation, the second source/drain epitaxy structures 240 may be doped with p-type dopants, such as boron (B), gallium (Ga), indium (In), aluminium (Al), or the like. In some embodiments, the first source/drain epitaxy structures 140 and the second source/drain epitaxy structures 240 may include dopants with opposite conductivity types. For example, if the first source/drain epitaxy structures 140 are doped with n-type dopants, the second source/drain epitaxy structures 240 are doped with p-type dopants. Similarly, if the first source/drain epitaxy structures 140 are doped with p-type dopants, the second source/drain epitaxy structures 240 are doped with n-type dopants. In the cross-sectional view of FIG. 32B, the second source/drain epitaxy structure 240 may include different widths than the first source/drain epitaxy structure 140.

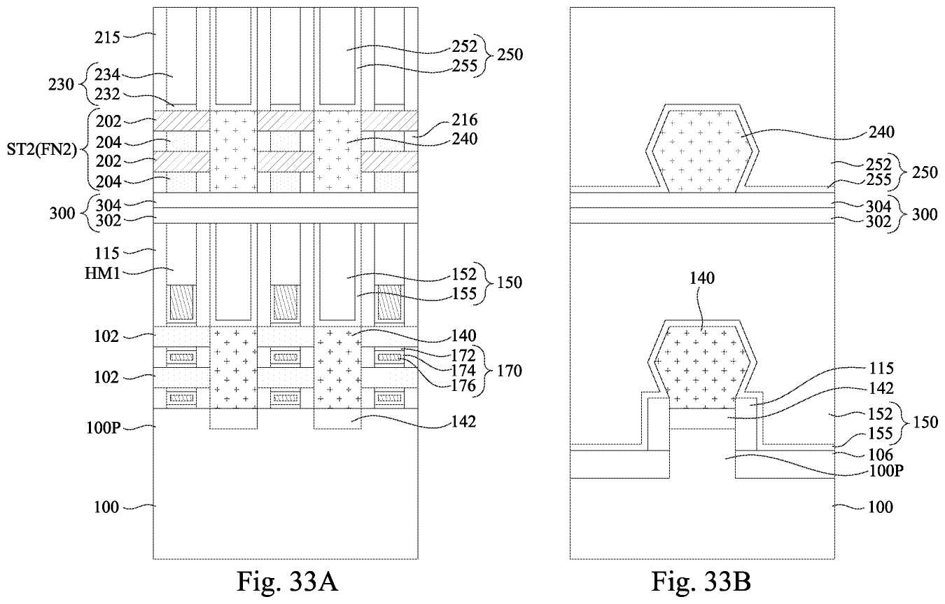

Reference is made to FIGS. 33A and 33B. A contact etch stop layer (CESL) 255 is formed covering the second source/drain epitaxy structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structures 230 are exposed. In some embodiments, the patterned masks MA2 are removed during the planarization process. In some embodiments, the CESL 255 and the ILD layer 252 can be collectively referred to as an isolation structure 250.

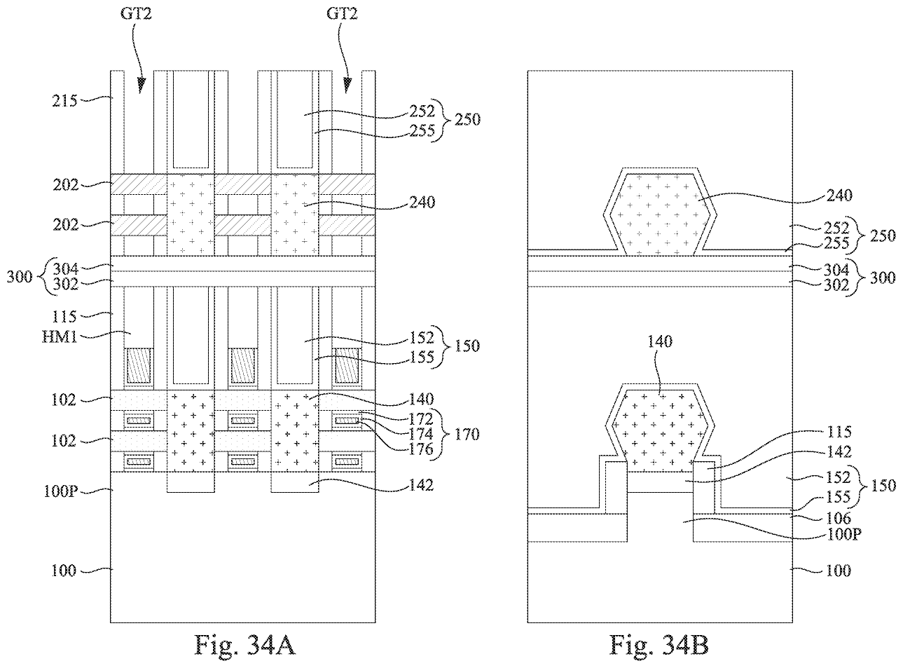

Reference is made to FIGS. 34A and 34B. The dummy gate structures 230 are removed to form gate trenches GT2 between each pair of the spacers 215. Then, an etching process is performed to remove the semiconductor layers 204 through the gate trenches GT2, such that that the semiconductor layers 202 are suspended over the bonding structure 300.

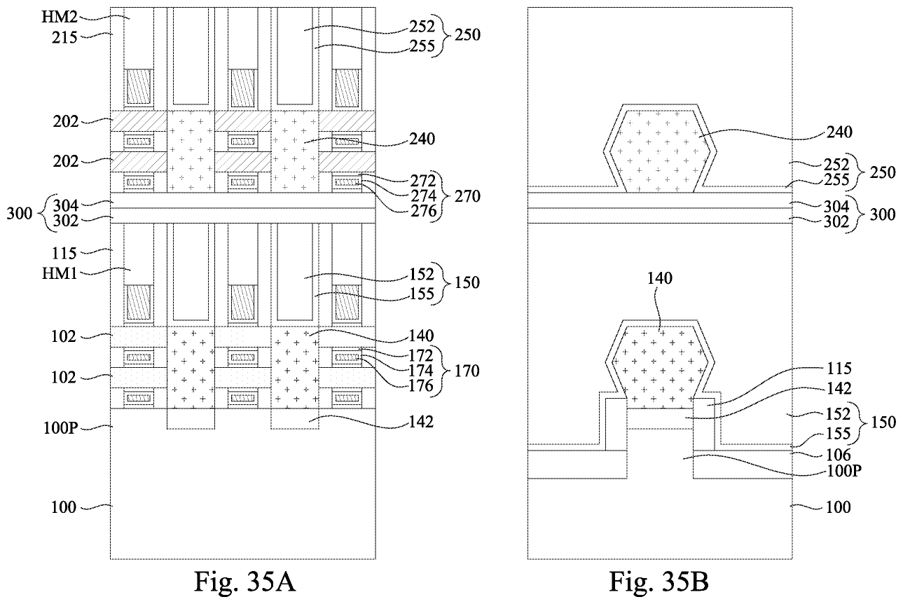

Reference is made to FIGS. 35A and 35B. Interfacial layers 272 are formed on exposed surfaces of the semiconductor layers 202, respectively. Afterwards, gate dielectric layers 274 are formed over the interfacial layers 272, and gate electrodes 276 are formed over the gate dielectric layers 274. Accordingly, second metal gate structures 270 are formed, in which each of the second metal gate structures 270 includes an interfacial layer 272, a gate dielectric layer 274, and a gate electrode 276. A planarization process, such as CMP, is performed to remove the excess interfacial layers 272, excess gate dielectric layers 274, and the excess gate electrodes 276 until the isolation structures 250 are exposed.

The second metal gate structures 270 are then etched back, such that top surfaces of the second metal gate structures 270 are lower than top surfaces of the spacers 215. Afterwards, hard masks HM2 are formed over the respectively second metal gate structures 270. The hard masks HM2 may be formed by, for example, depositing a dielectric layer over the etched back second metal gate structures 270, and then performing a planarization process, such as CMP, on the dielectric layer until the isolation structures 250 are exposed.

The first metal gate structure 170, the first source/drain epitaxy structures 140 on opposite sides of the first metal gate structure 170, and the semiconductor layers 102 that are in contact with the first source/drain epitaxy structures 140 may collectively serve as the first transistor TR1 as described in FIG. 1. In such condition, the semiconductor layers 102 that are in contact with the first source/drain epitaxy structures 140 may also be referred to as channel layers of the first transistor TR1. Similarly, the second metal gate structure 270, the second source/drain epitaxy structures 240 on opposite sides of the second metal gate structure 270, and the semiconductor layers 202 that are in contact with the second source/drain epitaxy structures 240 may collectively serve as the second transistor TR2 as described in FIG. 1. In such condition, the semiconductor layers 202 that are in contact with the second source/drain epitaxy structures 240 may also be referred to as channel layers of the second transistor TR2.

As shown in FIG. 35A, a bonding structure 300 is disposed between the first transistor TR1 and the second transistor TR2. The bottom surface of the bonding structure 300 may be in contact with the spacers 115, the isolation structures 150, and the hard masks HM1. The top surface of the bonding structure 300 may be in contact with the gate structures 270, the inner spacers 216, and the second source/drain epitaxy structures 240.

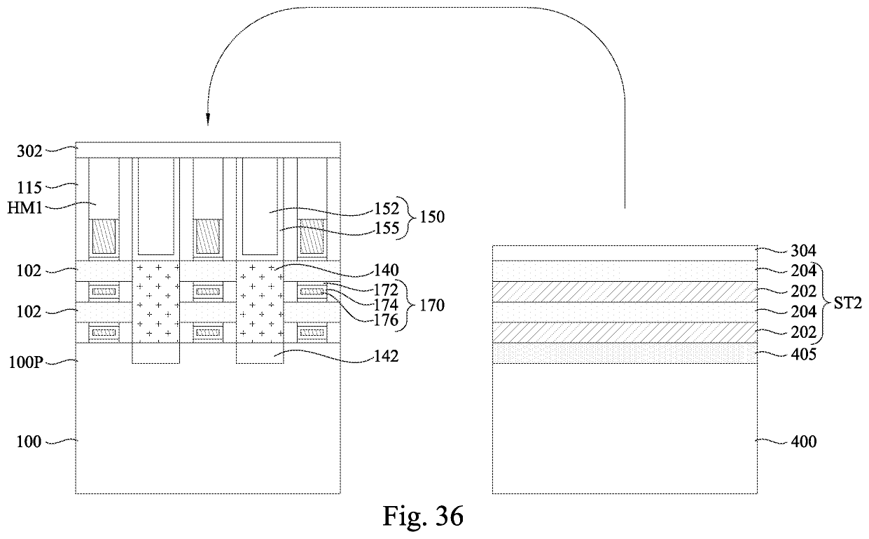

FIGS. 36 to 38B illustrate a method in various stages of forming a semiconductor device in accordance with some embodiments of the present disclosure. It is noted that FIGS. 36, 37A, and 38A include a same cross-sectional view as FIGS. 19A to 35A, and FIGS. 37B and 38B include a same cross-sectional view as FIGS. 19B to 35B. Although FIGS. 36 to 38B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements and some processes of FIGS. 36 to 38B may be similar to those described with respect to FIG. 1 and FIGS. 19A to 35B, and thus relevant details will not be repeated for brevity.

Reference is made to FIG. 36. FIG. 36 is similar to FIG. 26, while the difference between FIGS. 36 and 26 is that the substrate 200 as discussed in FIG. 26 is omitted. Instead, in FIG. 36, a substrate 400 is provided. Then, a crystalline orientation switching layer 405 is formed over the substrate 400. A second stack ST2 of alternating semiconductor layers 202 and semiconductor layers 204 are then formed over the crystalline orientation switching layer 405. A bonding layer 304 is formed over the second stack ST2.

In some embodiments, the substrate 400 may include a similar material as the substrate 100. For example, the substrate 400 may be made of silicon. The substrate 400 may include a first crystalline orientation that is the same as the crystalline orientation of the substrate 100. For example, the first crystalline orientation may be (100) crystalline orientation or (110) crystalline orientation.

The crystalline orientation switching layer 405 may include a second crystalline orientation that is different from the first crystalline orientation of the substrate 400. For example, if the first crystalline orientation is (100) crystalline orientation, the second crystalline orientation is (110) crystalline orientation. Similarly, if the first crystalline orientation is (110) crystalline orientation, the second crystalline orientation is (100) crystalline orientation.

The crystalline orientation switching layer 405 may be made of a dielectric material, such as a metal oxide. In some embodiments, the metal oxide may include yttrium oxide (Y₂O₃), cerium oxide (CeO₂), complex oxide system (such as (LaₓY₁₋ₓ)₂O₃ (LaYO), or containing more than two kinds of metal elements), or the like. In some embodiments, because oxygen and silicon include similar lattice constants, the silicon atoms may be bonded with oxygen atoms in the dielectric layer due to the less lattice mismatch, and thus the crystalline orientation switching layer 405 can be epitaxially grown over a semiconductor layer (e.g., the substrate 400) without strong lattice mismatch issue.

Furthermore, experiment results also show that the crystalline orientation of the crystalline orientation switching layer 405 is controllable during depositing the crystalline orientation switching layer 405 over a semiconductor layer (e.g., the substrate 400). More specifically, the crystalline orientation of the crystalline orientation switching layer 405 is temperature dependent during the deposition process. That is, by controlling the deposition temperature of the crystalline orientation switching layer 405, a crystalline orientation switching layer 405 having desired crystalline orientation can be obtained.

For example, in some embodiments where the substrate 400 is made of silicon and has a (100) crystalline orientation, the deposition temperature with about 400° C. to 500° C. (e.g., 450° C. in this case) may result in a crystalline orientation switching layer 405 having (110) crystalline orientation. If the deposition temperature is beyond the range, the crystalline orientation switching layer 405 may include unwanted crystalline orientation. For example, if the deposition temperature is about 60° C., the crystalline orientation switching layer 405 may include random-crystalline orientation (e.g., polycrystalline). If the deposition temperature is about 270° C., the crystalline orientation switching layer 405 may include (111) crystalline orientation.

Based on the above discussion, it can be seen that by selecting the material and the deposition temperature of the crystalline orientation switching layer 405, the crystalline orientation of the crystalline orientation switching layer 405 can be switched from the first crystalline orientation of the substrate 400 to a second crystalline orientation. The switched crystalline orientation is beneficial for allowing the following growth semiconductor layers 202 and 204 having a different crystalline orientation than the substrate 400.

The semiconductor layers 202 and 204 are alternately deposited over the crystalline orientation switching layer 405. Due to the nature of epitaxial growth, the semiconductor layers 202 and 204 tend to have a same crystalline orientation as the crystalline orientation switching layer 405. Thus, the semiconductor layers 202 and 204 may also include a second crystalline orientation the same as the crystalline orientation switching layer 405.

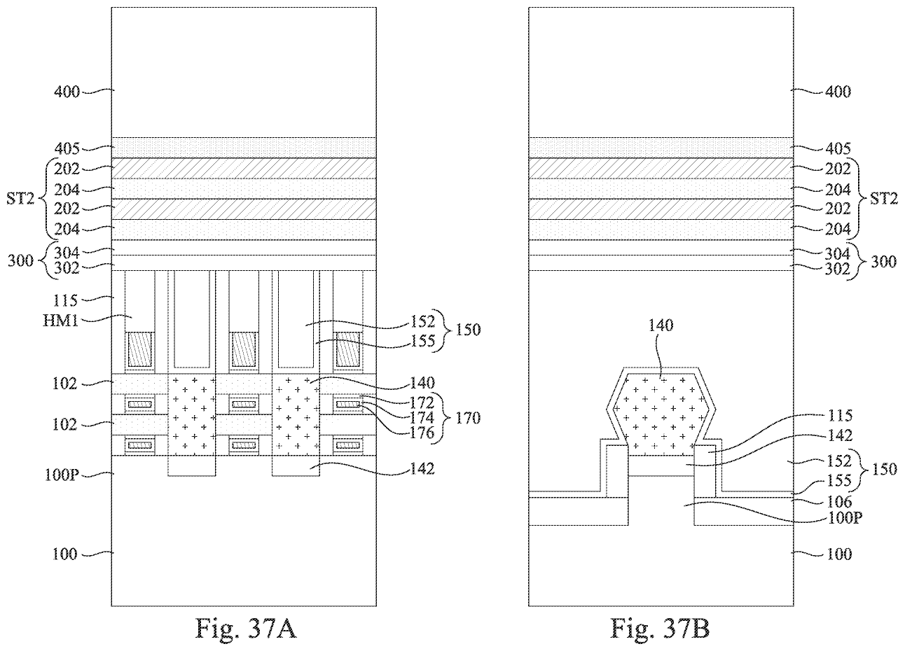

Reference is made to FIGS. 37A and 37B. The substrate 100 is bonded to the substrate 400. For example, in FIGS. 37A and 37B, the substrate 400 is flipped over by 180 degrees, such that the bonding layer 304 on the substrate 400 faces the bonding layer 302 on the substrate 100. Then, the bonding layers 302 and 304 are bonded with each other using suitable method as described above, and the bonded bonding layers 302 and 304 can be collectively referred to as a bonding structure 300.

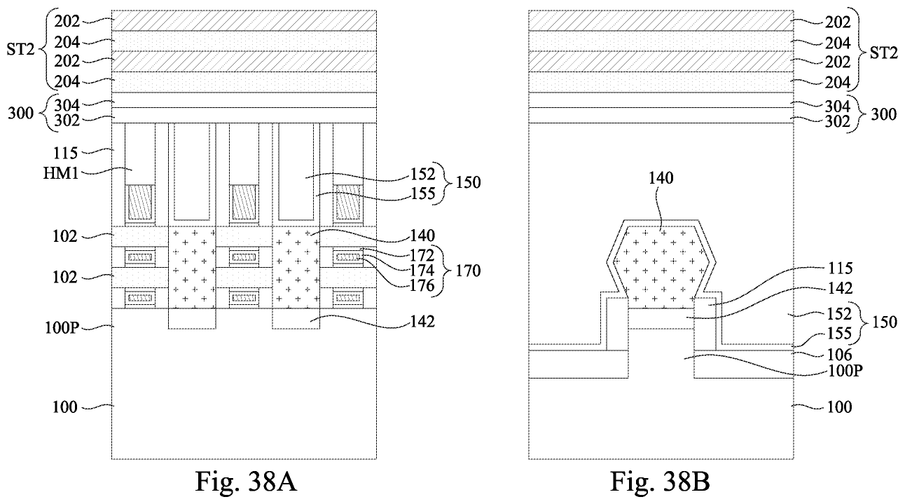

Reference is made to FIGS. 38A and 38B. A grinding process is performed on the backside of the substrate 400 (see FIGS. 37A and 37B), so as to remove the substrate 400 and the crystalline orientation switching layer 405 until the topmost semiconductor layer 202 is exposed. Then, the structures of FIGS. 38A and 38B may undergo the processes as discussed in FIGS. 29A to 35B, and the resulting structure is the same as structure shown in FIGS. 35A and 35B.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a CFET, which includes a first transistor and a second transistor above the first transistor. The channel layer of the first transistor and the channel layer of the second transistor may include different crystalline orientations. For example, a channel layer with (100) crystalline orientation is applied to an n-type transistor, while a channel layer with (110) crystalline orientation is applied to a p-type transistor. By selecting a suitable crystalline orientation of channel layer that is suitable for a corresponding conductivity type of transistor, the device performance may be improved. Moreover, a crystalline orientation switching layer is integrated in the manufacturing method of the CFET, the crystalline orientation switching layer allow the channel layers of the upper second transistor having a different crystalline orientation than the channel layers of the lower first transistor. Embodiments of the present disclosure enhance device performance with high mobility channels for both N- and P-channel. Moreover, the crystalline orientation switching layer with less lattice mismatch increases critical thickness, which will also improve the quality of the channel layers of the second transistor, and will make the structure become more flexible. The crystalline orientation switching layer also enables epitaxial growth on dielectric layer. The crystalline orientation switching layer also provides sufficient etching selectivity to the semiconductor materials.

In some embodiments of the present disclosure, a semiconductor device includes a first transistor and a second transistor over the first transistor, the second transistor having a different conductivity type than the first transistor. The first transistor includes a first semiconductor channel layer, in which the first semiconductor channel layer has a first crystalline orientation, a first gate structure wrapping around the first semiconductor channel layer, and first source/drain epitaxy structures on opposite ends of the first semiconductor channel layer. The second transistor includes a second semiconductor channel layer, wherein the second semiconductor channel layer has a second crystalline orientation different from the first crystalline orientation, a second gate structure wrapping around the second semiconductor channel layer, and second source/drain epitaxy structures on opposite ends of the second semiconductor channel layer.

In some embodiments, the first crystalline orientation is a (100) crystalline orientation and the first transistor is an n-type transistor, and the second crystalline orientation is a (110) crystalline orientation and the second transistor is a p-type transistor.

In some embodiments, the first crystalline orientation is a (110) crystalline orientation and the first transistor is a p-type transistor, and the second crystalline orientation is a (100) crystalline orientation and the first transistor is an n-type transistor.

In some embodiments, the first transistor is vertically between a substrate and the second transistor, and the substrate has a third crystalline orientation the same as the first crystalline orientation.

In some embodiments, the semiconductor device further includes a dielectric layer vertically between the first transistor and the second transistor.

In some embodiments, the semiconductor device further includes an isolation structure between one of the first source/drain epitaxy structures and one of the second source/drain epitaxy structures; a first semiconductor layer over the first gate structure of the first transistor and in contact with a sidewall of the isolation structure, in which the first semiconductor layer has a third crystalline orientation the same as the first crystalline orientation; and a second semiconductor layer below the second gate structure of the second transistor and in contact with the sidewall of the isolation structure, in which the second semiconductor layer has a fourth crystalline orientation the same as the second crystalline orientation.

In some embodiments, the semiconductor device further includes an isolation layer between the first semiconductor layer and the second semiconductor layer, and in contact with the sidewall of the isolation structure.

In some embodiments, the semiconductor device further includes a metal oxide layer vertically between the first transistor and the second transistor, in which the metal oxide layer has a third crystalline orientation the same as the second crystalline orientation.

In some embodiments of the present disclosure, a semiconductor device includes a first transistor, a second transistor above the first transistor, and a dielectric layer. The first transistor includes a first semiconductor channel layer, a first gate structure wrapping around the first semiconductor channel layer, and first source/drain epitaxy structures on opposite ends of the first semiconductor channel layer. The second transistor includes a second semiconductor channel layer, in which the second semiconductor channel layer has a first crystalline orientation, a second gate structure wrapping around the second semiconductor channel layer, and second source/drain epitaxy structures on opposite ends of the second semiconductor channel layer. The dielectric layer is vertically between the first gate structure and the second gate structure, in which the dielectric layer has a second crystalline orientation the same as the first crystalline orientation. An isolation structure is between one of the first source/drain epitaxy structures and one of the second source/drain epitaxy structures.

In some embodiments, the dielectric layer is made of a metal oxide.

In some embodiments, the metal oxide includes yttrium oxide or cerium oxide.

In some embodiments, the first semiconductor channel layer has a third crystalline orientation different from the first and second crystalline orientations.

In some embodiments, the semiconductor device further includes a first semiconductor layer in contact with a bottom surface of the dielectric layer, and a second semiconductor layer in contact with a top surface of the dielectric layer, in which the first semiconductor layer and the second semiconductor layer have different crystalline orientations.

In some embodiments, the dielectric layer is in contact with the isolation structure.

In some embodiments of the present disclosure, a method includes forming a first stack of alternating first semiconductor channel layers and first sacrificial layers over a first substrate, in which the first semiconductor channel layers have a first crystalline orientation; forming a second stack of alternating second semiconductor channel layers and second sacrificial layers over the first stack, in which the first semiconductor channel layers have a second crystalline orientation different from the first crystalline orientation; forming first source/drain epitaxy structures on opposite ends of each of the first semiconductor channel layers; forming second source/drain epitaxy structures on opposite ends of each of the second semiconductor channel layers; replacing the first sacrificial layers with a first gate structure, the first gate structure wrapping around each of the first semiconductor channel layers; and replacing the second sacrificial layers with a second gate structure, the second gate structure wrapping around each of the second semiconductor channel layers.

In some embodiments, the method further includes depositing a crystalline orientation switching layer over the first stack, in which the second stack is formed over the crystalline orientation switching layer, and in which the crystalline orientation switching layer has a third crystalline orientation that is different from the first crystalline orientation and is the same as the second crystalline orientation.

In some embodiments, the method further includes replacing the crystalline orientation switching layer with an isolation layer prior to forming the first source/drain epitaxy structures.

In some embodiments, the crystalline orientation switching layer is made of a metal oxide.

In some embodiments, the first crystalline orientation is (100) crystalline orientation, and in which the crystalline orientation switching layer is formed on a topmost one of the first semiconductor channel layers, and the crystalline orientation switching layer is deposited under a temperature in a range from about 400° C. to about 500° C., such that the third crystalline orientation is (110) crystalline orientation.

In some embodiments, forming the second stack of alternating second semiconductor channel layers and second sacrificial layers over the first stack includes forming the second stack of alternating second semiconductor channel layers and second sacrificial layers over a second substrate, in which the second substrate has a third crystalline orientation the same as the second crystalline orientation; forming a first bonding layer over the first stack of alternating first semiconductor channel layers and first sacrificial layers; forming a second bonding layer over the second stack of alternating second semiconductor channel layers and second sacrificial layers; bonding the first bonding layer and the second bonding layer; and removing the second substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first transistor, comprising:
a first semiconductor channel layer, wherein the first semiconductor channel layer has a first crystalline orientation;
a first gate structure wrapping around the first semiconductor channel layer; and
first source/drain epitaxy structures on opposite ends of the first semiconductor channel layer; and
a second transistor over the first transistor and having a different conductivity type than the first transistor, comprising:
a second semiconductor channel layer, wherein the second semiconductor channel layer has a second crystalline orientation different from the first crystalline orientation;
a second gate structure wrapping around the second semiconductor channel layer; and
second source/drain epitaxy structures on opposite ends of the second semiconductor channel layer.

2. The semiconductor device of claim 1, wherein the first crystalline orientation is a (100) crystalline orientation and the first transistor is an n-type transistor, and the second crystalline orientation is a (110) crystalline orientation and the second transistor is a p-type transistor.

3. The semiconductor device of claim 1, wherein the first crystalline orientation is a (110) crystalline orientation and the first transistor is a p-type transistor, and the second crystalline orientation is a (100) crystalline orientation and the first transistor is an n-type transistor.

4. The semiconductor device of claim 1, wherein the first transistor is vertically between a substrate and the second transistor, and the substrate has a third crystalline orientation the same as the first crystalline orientation.

5. The semiconductor device of claim 1, further comprising a dielectric layer vertically between the first transistor and the second transistor.

6. The semiconductor device of claim 1, further comprising:
an isolation structure between one of the first source/drain epitaxy structures and one of the second source/drain epitaxy structures;
a first semiconductor layer over the first gate structure of the first transistor and in contact with a sidewall of the isolation structure, wherein the first semiconductor layer has a third crystalline orientation the same as the first crystalline orientation; and
a second semiconductor layer below the second gate structure of the second transistor and in contact with the sidewall of the isolation structure, wherein the second semiconductor layer has a fourth crystalline orientation the same as the second crystalline orientation.

7. The semiconductor device of claim 6, further comprising an isolation layer between the first semiconductor layer and the second semiconductor layer, and in contact with the sidewall of the isolation structure.

8. The semiconductor device of claim 1, further comprising a metal oxide layer vertically between the first transistor and the second transistor, wherein the metal oxide layer has a third crystalline orientation the same as the second crystalline orientation.

9. A semiconductor device, comprising:
a first transistor, comprising:
a first semiconductor channel layer;
a first gate structure wrapping around the first semiconductor channel layer; and
first source/drain epitaxy structures on opposite ends of the first semiconductor channel layer;
a second transistor above the first transistor, comprising:
a second semiconductor channel layer, wherein the second semiconductor channel layer has a first crystalline orientation;
a second gate structure wrapping around the second semiconductor channel layer; and
second source/drain epitaxy structures on opposite ends of the second semiconductor channel layer;
a dielectric layer vertically between the first gate structure and the second gate structure, wherein the dielectric layer has a second crystalline orientation the same as the first crystalline orientation; and
an isolation structure between one of the first source/drain epitaxy structures and one of the second source/drain epitaxy structures.

10. The semiconductor device of claim 9, wherein the dielectric layer is made of a metal oxide.

11. The semiconductor device of claim 10, wherein the metal oxide comprises yttrium oxide or cerium oxide.

12. The semiconductor device of claim 9, wherein the first semiconductor channel layer has a third crystalline orientation different from the first and second crystalline orientations.

13. The semiconductor device of claim 9, further comprising:
a first semiconductor layer in contact with a bottom surface of the dielectric layer; and
a second semiconductor layer in contact with a top surface of the dielectric layer, wherein the first semiconductor layer and the second semiconductor layer have different crystalline orientations.

14. The semiconductor device of claim 9, wherein the dielectric layer is in contact with the isolation structure.

15. A method, comprising:
forming a first stack of alternating first semiconductor channel layers and first sacrificial layers over a first substrate, wherein the first semiconductor channel layers have a first crystalline orientation;
forming a second stack of alternating second semiconductor channel layers and second sacrificial layers over the first stack, wherein the first semiconductor channel layers have a second crystalline orientation different from the first crystalline orientation;
forming first source/drain epitaxy structures on opposite ends of each of the first semiconductor channel layers;
forming second source/drain epitaxy structures on opposite ends of each of the second semiconductor channel layers;
replacing the first sacrificial layers with a first gate structure, the first gate structure wrapping around each of the first semiconductor channel layers; and
replacing the second sacrificial layers with a second gate structure, the second gate structure wrapping around each of the second semiconductor channel layers.

16. The method of claim 15, further comprising depositing a crystalline orientation switching layer over the first stack, wherein the second stack is formed over the crystalline orientation switching layer, and wherein the crystalline orientation switching layer has a third crystalline orientation that is different from the first crystalline orientation and is the same as the second crystalline orientation.

17. The method of claim 16, further comprising replacing the crystalline orientation switching layer with an isolation layer prior to forming the first source/drain epitaxy structures.

18. The method of claim 16, wherein the crystalline orientation switching layer is made of a metal oxide.

19. The method of claim 18, wherein the first crystalline orientation is (100) crystalline orientation, and wherein the crystalline orientation switching layer is formed on a topmost one of the first semiconductor channel layers, and the crystalline orientation switching layer is deposited under a temperature in a range from about 400° C. to about 500° C., such that the third crystalline orientation is (110) crystalline orientation.

20. The method of claim 15, wherein forming the second stack of alternating second semiconductor channel layers and second sacrificial layers over the first stack comprises:
forming the second stack of alternating second semiconductor channel layers and second sacrificial layers over a second substrate, wherein the second substrate has a third crystalline orientation the same as the second crystalline orientation;
forming a first bonding layer over the first stack of alternating first semiconductor channel layers and first sacrificial layers;
forming a second bonding layer over the second stack of alternating second semiconductor channel layers and second sacrificial layers;
bonding the first bonding layer and the second bonding layer; and
removing the second substrate.
